(19) United States
(12) Patent Application Publication
(10) Pub. No.: US 2007/0126347 A1
(43) Pub. Date: Jun. 7, 2007

(54) OLEDS with improved efficiency

(75) Inventors: Viktor V. Jarikov, Rochester, NY (US); Kevin P. Klubek, West Henrietta, NY (US); Liang-Sheng Liao, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/293,656

(22) Filed: Dec. 1, 2005

(51) Int. Cl. H01L 51/54

(52) U.S. Cl. 313/506; 313/504; 428/690; 428/917; 428/212; 257/102; 257/103; 257/E51.049; 257/E51.05; 257/E51.051

(57) ABSTRACT

An organic light-emitting device, comprising a substrate; an anode and a cathode; a first hole-transport layer provided over the anode and having at least a first material; a second hole-transport layer provided over the first hole-transport layer, and having at least a second material; at least one light-emitting layer disposed over the second hole-transport layer wherein the light-emitting layer(s) includes a host, a dopant, and a hole-trapping material; an improved electron-transport layer disposed between the light-emitting layer(s) and the cathode.

### CROSS REFERENCE TO RELATED APPLICATION

Reference is made to commonly-assigned U.S. patent application Ser. No. 10/889,654 filed Jul. 12, 2004, entitled “Hole-Trapping Materials for Improved OLED Efficiency” by Viktor V. Jarikov, the disclosure of which is incorporated herein.

### FIELD OF THE INVENTION

This invention relates to an electroluminescent (EL) device which provides improved electroluminescent efficiency and includes a hole-transport region including either multiple layers or multiple components in a single layer, a light-emitting region including at least one light-emitting layer which includes a host, a dopant, and a hole-trapping material, and an electron-transport region including either multiple layers or multiple components in a single layer.

### BACKGROUND OF THE INVENTION

Organic light-emitting diodes (OLED), also known as organic electroluminescent (EL) devices, are a class of electronic devices that emit light in response to an electrical current applied to the device. The structure of an OLED device generally includes an anode, an organic EL medium, and a cathode. The term organic EL medium herein refers to organic materials or layers of organic materials disposed between the anode and the cathode in the OLED device. The organic EL medium can include low molecular weight compounds, high molecular weight polymers, oligomers of low molecular weight compounds, or biomaterials in the form of a thin film or a bulk solid. The medium can be amorphous or crystalline. Organic electroluminescent media of various structures have been described in the prior art. Dresner, in RCA Review, 30, 322 (1969), described a medium including a single layer of anthracene film. Tang et al., in Applied Physics Letters, 51, 913 (1987), Journal of Applied Physics, 65, 3610 (1989), and commonly assigned U.S. Pat. Nos. 4,769,292 and 4,885,211, report an EL medium with a multilayer structure of organic thin films, and demonstrated highly efficient OLED devices using such a medium. In some OLED device structures, the multilayer EL medium includes a hole-transport layer (HTL) adjacent to the anode, an electron-transport layer (ETL) adjacent to the cathode and, disposed in between these two layers, a light-emitting layer (LEL). Furthermore, in some preferred device structures, the light-emitting layer (LEL) is constructed of a doped organic film including an organic material as the host and a small concentration of a fluorescent compound as the dopant. Improvements in EL efficiency, chromaticity, and lifetime have been obtained in these doped OLED devices by selecting an appropriate dopant-host composition. The dopant, being the dominant emissive center, is selected to produce the desired EL colors. Examples of the doped light-emitting layer, as reported by Tang et al. in commonly assigned U.S. Pat. No. 4,769,292 and by Chen et al. in commonly assigned U.S. Pat. No. 5,908,581, are tris(8-quinolinol)aluminum (AlQ) as a host doped with coumarin dyes for green emitting OLEDs, and AlQ doped with 4-dicyanomethylene-4H-pyrans (DCMs) for orange-red emitting OLEDs. Shi et al., in commonly assigned U.S. Pat. No. 5,593,788, disclose that improved EL efficiency and color was obtained in an OLED device by using a quinacridone compound as the dopant in an AlQ host. Bryan et al., in commonly assigned U.S. Pat. No. 5,141,671, disclose a light-emitting layer containing perylene or a perylene derivative as a dopant in a blue emitting host. They showed that a blue emitting OLED device with an improved EL efficiency was obtained. In both disclosures, the incorporation of selected fluorescent dopants in the light-emitting layer is found to substantially improve the overall OLED device performance parameters.

Additional layers have been proposed to further improve device performance, e.g., as described in U.S. Pat. No. 4,769,292. This patent discloses the concept of a hole-injecting layer (HIL) located between the anode and the HTL. Materials including porphyrinic compounds have been disclosed by Tang in U.S. Pat. No. 4,356,429 for use in the HTL. Further improvements in device performance are taught in U.S. Pat. Nos. 4,539,507; 4,720,432; and 5,061,569 where the hole-transport layer utilizes an aromatic tertiary amine. Since these early inventions, further improvements in hole-transport and other device materials have resulted in improved device performance in attributes such as color, stability, luminance efficiency and manufacturability, e.g., as disclosed in U.S. Pat. Nos. 5,061,569; 5,409,783; 5,554,450; 5,593,788; 5,683,823; 5,908,581; 5,928,802; 6,020,078; and 6,208,077, amongst others. EP 891,121 and EP 1,029,909 suggest the use of biphenylene and phenylene diamine derivatives to improve hole injecting and/or transport and JP 11-273830 suggests the general use of naphthyldiamine derivatives in EL elements. Klubek et al. in U.S. Patent Application 2005/014018 A1 describes using dihydrophenazines as HIL materials, which leads to an improvement in electroluminescent efficiency.

The most common formulation of the doped light-emitting layer (LEL) includes only a single dopant in a host matrix. However, in a few instances, incorporation of more than one dopant in the light-emitting layer was found to be beneficial in improving EL efficiency. Co-doping of the light-emitting layer with anthracene derivatives results in devices with better EL efficiency as shown in JP 11-273861 and JP 07-284050. Using a LEL containing rubrene, a yellow emitting dopant, and DCJ, 4-(dicyanomethylene)-2-methyl-6-[2-(4-julolidyl)ethenyl]-4H-pyran, and a red emitting dopant in an AlQ host, it is possible to produce a red emitting OLED device with improved EL efficiency and color; see Hamada et al. in Applied Phys. Lett. 75, 1682 (1999), and EP 1 162 674 B1. Here rubrene functions as a co-dopant in mediating energy transfer from the AlQ host to the DCJ emitter. Hamada et al. also report, in U.S. Patent Application Publication 2004/0066139 A1, the use of a host material, such as NPB (N, N′-Di(naphthalene-1-yl) -N,N′-diphenyl benzidine), a light-emitting dopant such as DBzR (5,12-bis(4-(6-methylbenzothiazol-2-yl)phenyl)-6,11-diphenylnaphthacene), and a non-luminescent auxiliary dopant (i.e., an auxiliary dopant that does not emit light) such as tBuDPN (5,12-Bis(4-tert-butylphenyl)naphthacene) in an OLED device. An electron-injection layer including LiF is also reported. Hatwar et al., U.S. Pat. No. 6,475,648 describe a case where a host and three dopants are used in the light-emitting layer of an OLED device. For example, a combination of AlQ₃, 2% DCJTB (4-(dicyanomethylene)-2-(t-butyl)-6-[2-(4-julolidyl)ethenyl]-4H-pyran), 5% NPB, and 5% rubrene is reported. In some examples, LiF is also used as an electron-injection layer adjacent to the cathode.

Another attempt to improve the efficiency of EL devices involves using a mixture of host components in the light-emitting layer. Aziz et al., U.S. Pat. Nos. 6,614,175, 6,392,250, 6,392,339, and U.S. Patent Application Publications 2003/0134146 A1 and 2002/0135296 A1 report an organic light-emitting device that includes a mixed region. For example, a mixed region composed of a mixture of a hole-transport material, such as NPB, and an electron-transport material, commonly AlQ, and in some cases a low level of a dopant is present such as rubrene.

Doping light-emitting layers with hole-transport materials to assist in transport of charge carriers (holes) in order to improve electroluminescence (EL) efficiency has been described, for example, by Mori et al. in commonly assigned U.S. Pat. No. 5,281,489, by Aziz et al. in commonly assigned U.S. Pat. No. 6,392,339, by Hatwar et al. in commonly assigned U.S. Pat. No. 6,475,648, and by Matsuo et al. in EP 1 231 252 A2. These references disclose that high concentrations of hole-trapping materials, for example 50% or more, are required to provide the reported operational improvements. It has been disclosed by Hamada et al. in U.S. Published Patent Application 2004/0066139 A1 that hole-transport materials present in a light-emitting layer at concentrations of less than 5% by weight cannot satisfactorily function as an auxiliary dopant. Similarly, it has been disclosed by Kobori et al. in an unexamined application JP2001-52870 that the preferred concentration range for the hole-injection/transport component in a three-component light-emitting layer consisting of an electron-injection/transport material, hole-injection/transport material, and a dopant is more than 5% by weight, preferably more than 10% by weight, and more preferably more than 20% by weight. At such high concentration levels the hole-transport component of the light-emitting layer conducts holes rather than traps them. In the same application, Kobori et al. describe using a hole-injection layer (HIL) made of a para-phenylenediamine type material next to the anode and a hole-transport layer of a N,N,N,N-tetraarylbenzidine type material in between the HIL and the multiple LEL's of a white-emitting device, but they do not explain the advantages of such a structure.

In U.S. Pat. No. 6,753,098 B2, Aziz et al. describe the use of copper phthalocyanine (CuPc) as a HIL for a device having an LEL region composed of a mixed host having an electron-transport oxinoid compound, such as AlQ, and a hole-transport amine compound, such as NPB or TPD, and a dopant. However, they do not describe the effect of the CuPc HIL on the device efficiency and appear to use it as a thin (50-100 angstrom) buffer layer or a surface-modifying treatment layer for the ITO anode providing for improved adhesion and hole-injection.

Hamada et al. in U.S. Published Patent Application No. 2004/0066139 A1 describe a dual LEL white light emitting device structure, which includes a first HIL of CuPc followed by a second HIL of CFₓ, on top of which the common HTL of NPB is disposed. The use of the second HIL of CFₓ appears to enhance hole injection from the first HIL of CuPc into the NPB HTL and thus, lowers the drive voltage and leads to normal voltage drop across the NPB HTL, i.e. typically ˜0.001 V per angstrom.

Kobori et al. in U.S. Pat. No. 6,285,039 B1 describe a few cases where an LEL is a mixture of an N,N,N,N-tetraarylbenzidine with a metal oxinoid compound and a dopant, and they mention a possible HIL composed of a para-phenylenediamine type material and that in general the HIL material should have a lower oxidation potential than that of the hole-transport material. However, they do not explain the advantages of such a structure.

Song Shi et al. in U.S. Pat. No. 6,130,001 describe an OLED device with improved interface stability due to the elimination of heterojunctions between the HTL and LEL and the ETL and LEL, which suppresses aggregation and crystallization. The LEL consists of a metal quinolinolate (oxinoid) compound and an amine. Possible HIL's are mentioned, while preferred materials are CuPc and other phthalocyanines. Gebeyehu et al. in Synthetic Metals, 148 (2005) 205-211 describe highly efficient deep-blue OLEDs with doped charge transport layers, which lead to improved charge injection and transport and thus to lower drive voltage, and having a single-component LEL.

A number of researchers have reported the use of a thin layer of metal, metal oxide, metal fluoride, or other metal-releasing material located between the cathode and the light-emitting layer that acts as an electron-injection layer (EIL) and improves the efficiency of an EL device. For example, U.S. Pat. Nos. 6,563,262 and 6,340,537 report the use of a layer of metal oxide wherein the metal oxide is selected from the group including metal oxides, alkaline earth metal oxides, lanthanide metal oxides, and mixtures thereof U.S. Pat. No. 6,483,236 describes a thin layer of an alkaline metal fluoride formed on the organic light-emitting layer.

Instead of using a thin layer of metal, metal oxide, metal fluoride, or other metal-releasing material as an electron-injection layer, it is also known to use an organic layer that is doped with a metal. Kido and Matsumoto, Appl. Phys. Lett., 73, 2866 (1998) report improved efficiency by using such a metal doped organic layer. This layer can be used in an OLED as an electron-injection layer at the interface between a metal cathode and the light-emitting layer. A lithium doped layer of tris-(8-hydroxyquinoline) aluminum (AlQ) results in a lower barrier height for electron injection and higher electron conductivity vs. those for a layer of neat AlQ. This improves quantum efficiency.

Hasegawa et al., in WO 2003/044829, report a light-emitting element in which a layer of an organic compound, such as AlQ, contains a carbonate, for example Cs₂CO₃ and Li₂CO₃, as a dopant, and is in contact with a cathode.

Forrest et al., in U.S. Pat. No. 6,639,357, describe a highly transparent non-metallic cathode that includes a metal-doped organic electron-injection layer, which also functions as an exciton blocking or hole-blocking layer. This layer is produced by diffusing an ultra-thin layer of a highly electropositive metal such as Li throughout the layer.

The EL efficiency of OLED devices remains a potential limiting factor for OLED applications and competitiveness. Developing advanced materials and device configurations play an important role. It has been observed that the combined use of different materials constituting the hole-transport side and the electron-transport side as well as hosts and dopants in light-emitting layers, can lead to significantly improved device performance parameters, specifically electroluminescence (EL) efficiency, which is commonly measured in photons per electrons (p/e), watts of light per amp (W/A), and cd/A. Although EL efficiency has been improved significantly using doped light-emitting layers of various compositions, the problem of insufficient EL efficiency persists. Insufficient EL efficiency presents an obstacle for many desirable practical applications.

### SUMMARY OF THE INVENTION

It is an object of the present invention to provide efficient OLED devices producing visible light with significantly improved luminance yield.

This object is achieved by an organic light-emitting device including:

a) a substrate;

b) an anode and a cathode disposed over the substrate;

c) a first hole-transport layer provided over the anode and having at least a first material which is organic or inorganic, wherein the first material has an oxidation potential in the range of from 0 to +1.1 V vs. SCE;

d) a second hole-transport layer provided over the first hole-transport layer, and having at least a second material, which is organic, wherein
i) the second material has an oxidation potential that is in the range of from +0.4 to +1.4 V vs. SCE;
ii) the second material has an oxidation potential that is at least 0.2 V greater than the oxidation potential of the first material;
iii) the second material has a peak emission wavelength at 475 nm or shorter;

e) at least one light-emitting layer disposed over the second hole-transport layer wherein the light-emitting layer(s) includes a host, a dopant, and a hole-trapping material, wherein
i) the hole-trapping material is provided to be 0.1 to less than 15% by volume relative to its corresponding light-emitting layer volume, and has an oxidation potential in a range of from +0.4 to +1.1 V vs. SCE, wherein the oxidation potential is selected so that it is less than the oxidation potential of its corresponding host by at least 0.1 V (or the HOMO level for the hole-trapping material is closer to the vacuum level by at least 0.1 eV compared to the HOMO level of its corresponding host) in order to serve as a hole trap, and wherein the oxidation potential is further selected so as to avoid formation of a harmful charge transfer complex between the hole-trapping material and the host, and to avoid formation of a harmful charge transfer complex between the hole-trapping material and the dopant;
ii) the host of the light-emitting layer being selected to include at least one organic electrical charge transport material, which has an oxidation potential of +1.0 V or higher vs. SCE, and has a peak emission wavelength at 475 nm or shorter, and which when mixed with the hole-trapping material forms a continuous and substantially pin-hole-free layer; and
iii) the dopant of the light-emitting layer being selected to produce colored light and to have the energy of the emissive electronic state that is smaller than the energy of the corresponding (lowest excited singlet or lowest triplet) electronic state of each of the following: the second material, the host, and the hole-trapping material; and

f) an electron-transport layer disposed between the light-emitting layer(s) and the cathode wherein the electron-transport layer includes an electron-transport material which lowers or eliminates the barrier for electron injection from the metallic cathode into the electron-transport layer and enhances electron transport across the layer, where the barrier reduction and the transport enhancement are determined by testing a simple light-emitting device, wherein
i) the voltage drop across the electron-transport layer in the direction of the layer thickness is less than 0.007 V/angstrom at a drive current of 20 mA/cm² with a Mg:Ag (20:1) cathode; and
ii) the electron-transport material enhances or at least does not significantly reduce the electroluminescent efficiency of the test device.

The present invention also can be used in display devices or area lighting devices incorporating the electroluminescent device and a process for emitting light. The present invention is applicable to electroluminescent devices of all colors.

Following the selection criteria of this invention, OLED devices have been constructed having EL efficiency that approaches the theoretical maximum. The following discussion focuses on a blue emitting device. It has been discovered that the addition of certain hole trapping compounds to a blue light-emitting layer provided significant increases in EL efficiency. Further, addition of the hole-trapping materials at concentrations of less than 5% to a blue emission layer composed of a host and a dopant resulted in an improvement in EL efficiency (in p/e, W/A, and cd/A) by a factor of 1.3 to 2.5 times, resulting in ˜0.060-0.080 W/A. Further, in addition to having a hole-trapping material in an LEL, it has been discovered that the EL efficiency can be further improved by 1.3-2 times, resulting in 0.090-0.110 W/A, by employing dual hole-transport layers. The term dual hole-transport layers means that the hole-transport layer includes at least two sublayers made of two compounds having different oxidation potentials, as described below. Also, in addition to having a hole-trapping material in an LEL, it has been discovered that the EL efficiency can be further improved by 1.1-1.4 times, resulting in 0.070-0.090 W/A, by utilizing advanced electron-transport materials (which are easier to inject electrons into and are better electron transporters than for example commonly used AlQ) and/or by doping with an alkali metal in an electron-transport layer or sublayer, as described below. Furthermore, it has been discovered that the EL efficiency can be improved even further by an overall factor of 2-3 times, resulting in 0.100-0.130 W/A by employing (i) a hole-trapping material in an LEL, (ii) dual hole-transport layers and (iii) advanced electron-transport materials and/or doping with an alkali metal in an electron-transport layer or sublayer, as described below.

It has been further discovered that addition of the hole-trapping material to a blue-green light-emitting layer composed of a host and a dopant also results in a 1.1-1.3 times increase in EL efficiency, resulting in 0.110-0.120 W/A, when the dopant belongs to the class of styrylamines, naphthylvinylamines, and their derivatives. Also, in addition to having a hole-trapping material in an LEL, it has been discovered that the EL efficiency can be further improved by about 1.5 times, resulting in 0.130-0.150 W/A, by employing dual hole-transport layers, as described below. Also, in addition to having a hole-trapping material in an LEL, it has been discovered that the EL efficiency can be further improved by 1.1-1.2 times, resulting in 0.120-0.130 W/A, by utilizing advanced electron-transport materials and/or by doping with an alkali metal in an electron-transport layer or sublayer, as described below.

### BRIEF DESCRIPTION OF THE DRAWINGS

The drawings are necessarily of a schematic nature, since the individual layers are too thin and the thickness differences of the various elements too great to permit depiction to scale or to permit convenient proportionate scaling.

FIG. 1 is a schematic structure of an OLED with an organic EL medium; and

FIG. 2 and FIG. 3 are two schematic OLED structures showing two different configurations of the organic EL medium.

### DETAILED DESCRIPTION OF THE INVENTION

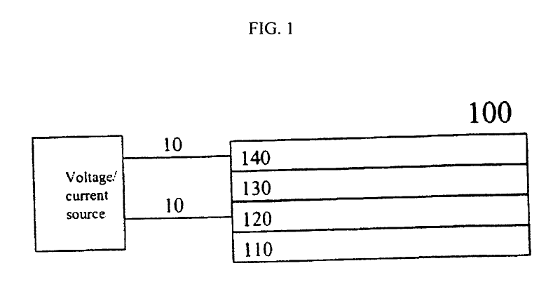

FIG. 1 illustrates the structure of an OLED device of the simplest construction practiced in the present invention. In this structure, OLED device 100 includes a substrate 110, an anode 120, an EL medium 130, and a cathode 140 disposed over substrate 110. In operation, an electrical current is passed through the OLED by connecting an external current or voltage source with electrical conductors 10 to the anode 120 and the cathode 140, causing light to be emitted from the EL medium. The light can exit through either the anode 120 and the substrate 110 or the cathode 140, or both, as desired and depending on their optical transparencies. The EL medium includes a single layer or a multilayer of organic materials.

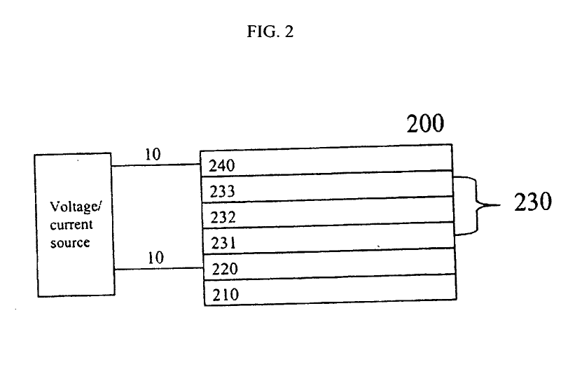

FIG. 2 illustrates the structure of another OLED device of the present invention. In this structure, OLED device 200 includes a substrate 210 and an EL medium 230 disposed between an anode 220 and a cathode 240. EL medium 230 includes a hole-transport layer 231 adjacent to the anode 220, an electron-transport layer 233 adjacent to the cathode 240, and a light-emitting layer 232 disposed between the hole-transport layer 231 and the electron-transport layer 233. In operation, an electrical current is passed through the OLED device by connecting an external current or voltage source with electrical conductors 10 to the anode 220 and the cathode 240. This electrical current, passing through the EL medium 230, causes light to be emitted primarily from the light-emitting layer 232. Hole-transport layer 231 carries the holes, that is, positive electronic charge carriers, from the anode 220 to the light-emitting layer 232. Electron-transport layer 233 carries the electrons, that is, negative electronic charge carriers, from the cathode 240 to the light-emitting layer 232. The recombination of holes and electrons produces light emission, that is, electroluminescence, from the light-emitting layer 232.

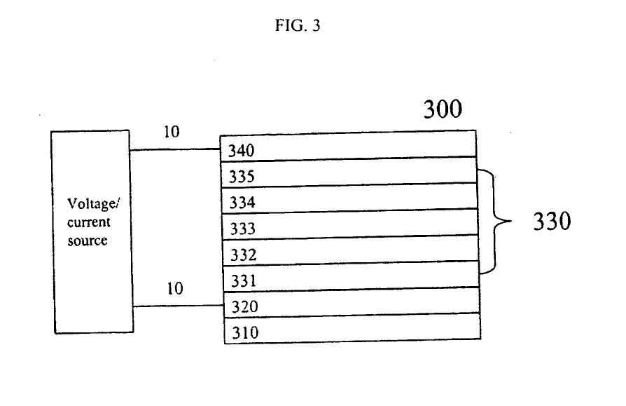

FIG. 3 illustrates yet another structure of an OLED device of the present invention. In this structure, OLED device 300 includes a substrate 310 and an EL medium 330 disposed between an anode 320 and a cathode 340. The surface of the anode 320 may be modified by another thin layer. EL medium 330 includes a first hole-transport layer 331 (also sometimes called a hole-injection layer), a second hole-transport layer 332, a light-emitting layer 333 (which can be a single layer or multiple layers), an electron-transport layer 334 (which can be a single layer or multiple layers), and an electron-injection layer 335. Similar to the OLED device 200 of FIG. 2, the recombination of electrons and holes produces emission primarily from the light-emitting layer 333. The provision of the first hole-transport layer (or hole-injection layer) 331 and the electron-injection layer 335 serves to reduce the barriers for carrier injection from the respective electrodes and/or increase the efficiency of the charge transport. Consequently, the drive voltage required for the OLED device can be reduced.

Substrate

The substrate 110, 210, or 310 (of FIGS. 1, 2, and 3 respectively) can either be light transmissive or opaque, depending on the intended direction of light emission. The light transmissive property is desirable for viewing the EL emission through the substrate. The transparent substrate may contain, or have built up on it, various electronic structures or circuitry (e.g., low temperature poly-silicon TFT structures) so long as a transparent region or regions remain. Transparent glass or plastic is commonly employed in such cases. The substrate can be a complex structure including multiple layers of materials. This is typically the case for active matrix substrates wherein TFTs are provided below the OLED layers. It is still necessary that the substrate, at least in the emissive pixelated areas, be included of largely transparent materials such as glass or polymers.

For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials. Again, the substrate can be a complex structure including multiple layers of materials such as found in active matrix TFT designs. Of course, it is necessary to provide in these device configurations a light transparent top electrode.

The substrate, in some cases, may actually constitute the anode or cathode.

Anode

The OLED device of this invention is typically provided over a supporting substrate where either the cathode or anode can be in contact with the substrate. The electrode in contact with the substrate is conveniently referred to as the bottom electrode. Conventionally, the bottom electrode is the anode, but this invention is not limited to that configuration.

The conductive anode layer 120, 220, or 320 (of FIGS. 1, 2, and 3 respectively) is formed over the substrate and, when EL emission is viewed through the anode, should be transparent or substantially transparent to the emission of interest. Common transparent anode materials used in this invention are indium-tin oxide and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used. For applications where EL emission is viewed through the top electrode, the cathode, the transmissive characteristics of the anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes can be polished prior to application of other layers to reduce surface roughness so as to reduce short circuits or enhance reflectivity.

The anode surface is usually cleaned with water-based detergent and dried using a commercial glass scrubber tool. It is usually subsequently treated with an oxidative plasma or UV/ozone to further clean and condition the anode surface and adjust its work function.

The anode surface is often modified, for example by a thin layer of copper phthalocyanine (CuPc) as described by Van Slyke et al. in Appl. Phys. Lett., 69, 2160 (1996), plasma-deposited fluorocarbon polymers (CFₓ) as described in U.S. Pat. No. 6,208,075, a strong oxidizing agent such as dipyrazino[2,3-f:2′,3′-h]quinoxalinehexacarbonitrile (DPQHC) as described in U.S. Pat. No. 6,720,573 B2 and in U.S. Published Application 2004/113547 A1, or another strong oxidizing agent, which can be organic, such as F₄TCNQ or inorganic, such as molybdenum oxide, FeCl₃, or FeF₃. 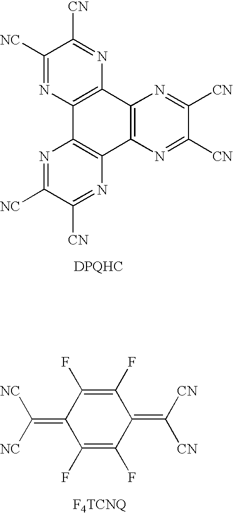
Hole-Transport Layer(s)

To achieve the objects of the present invention, certain HTL materials and structures are required in addition to the LEL and ETL specifications, both of which are described below. Thus, the hole-transport layer, disposed between the anode and the light-emitting layer(s), includes at least two hole-transport layers, wherein:

i) a first hole-transport layer provided over the anode has at least a first material which is organic or inorganic (where inorganic specifically includes metal oxides, metal nitrides, metal carbides, complexes of a metal ion and organic ligands, and complexes of a transition metal ion and organic ligands), wherein the first material has an oxidation potential in the range of from 0 to +1.1 V vs. SCE; and

ii) a second hole-transport layer provided over the first hole-transport layer has at least a second material, which is organic, wherein
i′) the second material has an oxidation potential that is in the range of from +0.4 to +1.4 V vs. SCE;
ii′) the second material has an oxidation potential that is at least 0.2 V greater than the oxidation potential of the first material (or the second material has the HOMO level which is at least 0.2 eV further from the vacuum level than the HOMO level of the first material); and
iii′) the second material has a peak emission wavelength at 475 nm or shorter.

Thus, one requirement of the current invention is the presence of a thermodynamic barrier of at least 0.2 eV for hole injection from the first HTL into the second HTL. During device operation, this barrier would force some holes to collect at the interface between the first HTL and the second HTL on the first HTL side, which would reduce the steady-state concentration of holes collected at the interface between the second HTL and the LEL on the second HTL side. The barrier would also elevate the electric field strength in the second HTL and thus, will elevate the electric field strength precisely at the interface between the second HTL and the LEL. As a result of the latter, it is expected that the relative rate of injection of holes from the second HTL into the LEL will increase.

The total thickness of the first and the second HTL is usually defined by the maximum in the optical response function for the optical microcavity formed between the glass substrate and the cathode. The relative thicknesses of the first and second HTL's are defined by their effect on EL efficiency, which needs to be maximized, and on the drive voltage, which needs to be minimized to result in better power efficiency. Therefore, to keep the drive voltage low, it is often advantageous to increase the thickness of the first HTL to a maximum allowable value beyond which it starts to reduce the EL efficiency. The second HTL may be as thin as 50 Å and as thick as 1,500 Å.

Suitable materials for use in the first HTL include, but are not limited to porphyrin and phthalocyanine compounds as described in U.S. Pat. No. 4,720,432, phosphazine compounds, and certain aromatic amine compounds which are stronger electron donors than conventional HTL materials, such as N,N,N,N-tetraarylbenzidine compounds. For example, materials useful in the first HTL can have their Eₒₓ be dominated by one of the following moieties:
para-phenylenediamine, such as those described in EP 0 891 121 A1 and EP 1,029,909 A1 or other di- and triaminobenzenes,
dihydrophenazine,
2,6-diaminonaphthalene and other polyaminated (di-, tri-, tetra-, etc. amino) naphthalene and their mixtures,
2,6-diaminoanthracene, 9,10-diaminoanthracene, and other polyaminated anthracenes,
2,6,9,10-tetraaminoanthracene,
anilinoethylene,
N,N,N,N-tetraarylbenzidine,
mono- or polyaminated perylene and their mixtures,
mono- or polyaminated coronene and their mixtures,
polyaminated pyrene and their mixtures,
mono- or polyaminated fluoranthene and their mixtures,
mono- or polyaminated chrysene and their mixtures,
mono- or polyaminated anthanthrene and their mixtures,
mono- or polyaminated triphenylene and their mixtures, or
mono- or polyaminated tetracene and their mixtures.

Some of the exemplary amine compounds are:
Tris(p-aminophenyl)amine (CAS 5981-09-9),
4,4′,4″-Tris(N,N-diphenylamino)-triphenylamine (CAS 105389-36-4);
4,4′,4″-tris[(3-methylphenyl)phenylamino]triphenylamine (mTDATA)
4,4′,4″-Tris(N-(2-naphthyl)-N-phenylamino)-triphenylamine (CAS 185690-41-9);
4,4′,4″-Tris(N-(l -naphthyl)-N-phenylamino)triphenylamine (CAS 185690-39-5);
N,N,N′,N′-Tetrakis(4-dibutylaminophenyl)-p-phenylenediamine (CAS 4182-80-3);
Tris[(4-diethylamino)phenyl]amine (CAS 47743-70-4);
4,4′-Bis[di(3,5-xylyl)amino]-4″-phenyltriphenylamine (CAS 249609-49-2);
5,10-Dihydro-5,10-dimethyl-phenazine;
9,14-Dihydro-9,14-dimethyl-dibenzo[a,c]phenazine;
9,14-Dihydro-9,14-dimethyl-phenanthro[4,5-abc]phenazine;
6,13-Dimethyldibenzo[b,i]phenazine;
5,10-Dihydro-5,10-diphenylphenazine;
Tetra(N,N-diphenyl-4-aminophenyl)ethylene;
Tetrakis[p-(dimethylamino)phenyl]ethylene;
N,N,N′,N′-tetra-2-naphthalenyl-6,12-chrysenediamine;
N-[2-(diphenylamino)-6-naphthalenyl]-N-3-perylenyl-N′,N′-diphenyl-2,6-naphthalenediamine;
N,N,N′,N′-tetrakis([1,1′-biphenyl]-4-yl)-2,6-naphthalenediamine;
N,N,N′,N′-tetrakis(4-methylphenyl)-dibenzo[def,mno]chrysene-6,12-diamine;
N,N,N′,N′-tetraphenyl-9,10-diphenylanthracene-2,6-diamine;
N,N,N′,N′,N″,N″,N″′,N″′-octaphenyl-anthracene-2,6,9,10-tetraamine;
N,N,N′,N′-tetrakis(4-methoxyphenyl)-benzidine;
N,N,N′,N′-tetraphenyl-perylene-3,9-diamine;
N,N,N′,N′,N″,N″,N″′,N″′-octaphenyl-coronene-1,4,7,10-tetraamine;
N,N,N′,N′,N″,N″,N″′,N″′-octaphenyl-pyrene-1,3,6,8-tetraamine;
N,N,N′,N′-tetrakis(3-methylphenyl)-3,9-fluoranthenediamine;
10,10′-(3,9-fluoranthenediyl)bis-10H-phenoxazine;
N,N,N′,N′,N″,N″-hexaphenyl-2,6,11-triphenylenetriamine;
N,N,N′,N′,N″,N″,N″′,N″′,N″″,N″″,N″″′,N″″′-dodecaphenyl-2,3,6,7,10,11-triphenylenehexamine;
N,N,N′,N′-tetraphenyl-5,11-naphthacenediamine; or
N,N′-di-1-naphthalenyl-N,N′-diphenyl-5,12-naphthacenediamine.

The first material, which composes the first hole-transport layer, may include an inorganic compound(s), such as metal oxide, metal nitride, metal carbide, a complex of a metal ion and organic ligands, and a complex of a transition metal ion and organic ligands.

While not necessary, the first material may also be composed of two components: for example, one of the organic materials mentioned above, such as an amine compound, doped with a strong oxidizing agent, such as dipyrazino[2,3-f:2′,3′-h]quinoxalinehexacarbonitrile, F₄TCNQ, or FeCl₃.

While not necessary, the first material, for example, an amine compound, may be disposed on top of a layer, which modifies the anode surface and is made of a strong oxidizing agent, such as CFₓ, dipyrazino[2,3-f:2′,3′-h]quinoxalinehexacarbonitrile, F₄TCNQ, molybdenum oxide, FeCl₃, or FeF₃.

Suitable materials for use in the second HTL include, but are not limited to amine compounds, that is, structures having an amine moiety. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al. U.S. Pat. No. 3,567,450 and U.S. Pat. No. 3,658,520. A more preferred class of aromatic tertiary amines are those which include at least two aromatic tertiary amine moieties as described in U.S. Pat. Nos. 4,720,432 and 5,061,569.

Exemplary of contemplated amine compounds are those satisfying the following structural formula: 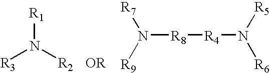
wherein:
substituents R₄ and R₈ are each individually aryl, or substituted aryl of from 5 to 30 carbon atoms, heterocycle containing at least one nitrogen atom, or at least one oxygen atom, or at least one sulfur atom, or at least one boron atom, or at least one phosphorus atom, or at least one silicon atom, or any combination thereof; substituents R₄ and R₈ each individually or together (as one unit denoted “R₈-R₄”) representing an aryl group such as benzene, naphthalene, anthracene, tetracene, pyrene, perylene, chrysene, phenathrene, triphenylene, tetraphene, coronene, fluoranthene, pentaphene, ovalene, picene, anthanthrene and their homologs and also their 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FIAn, 1,2-FlAn, 3,4-Per, 7,8-FlAn, 8,9-FlAn, 2,3-TriP, 1,2-TriP, 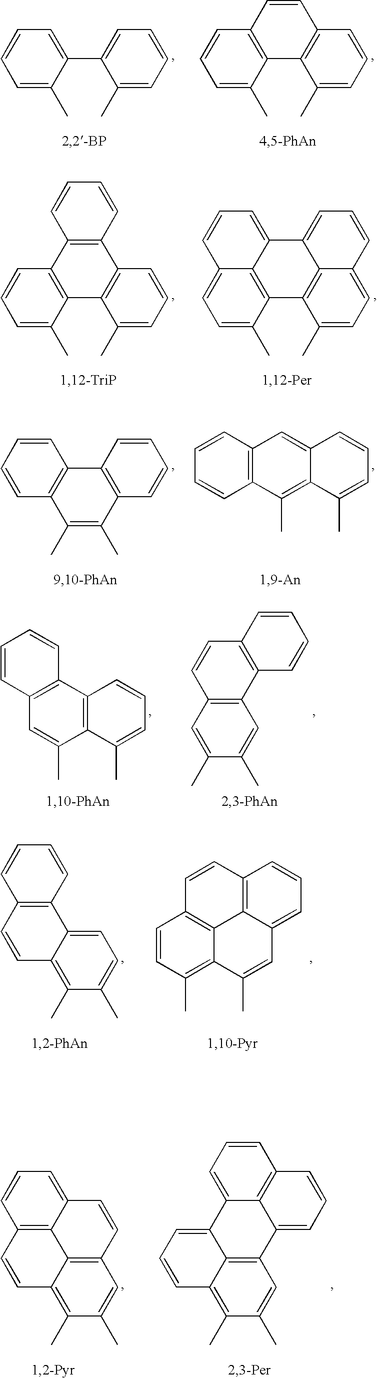 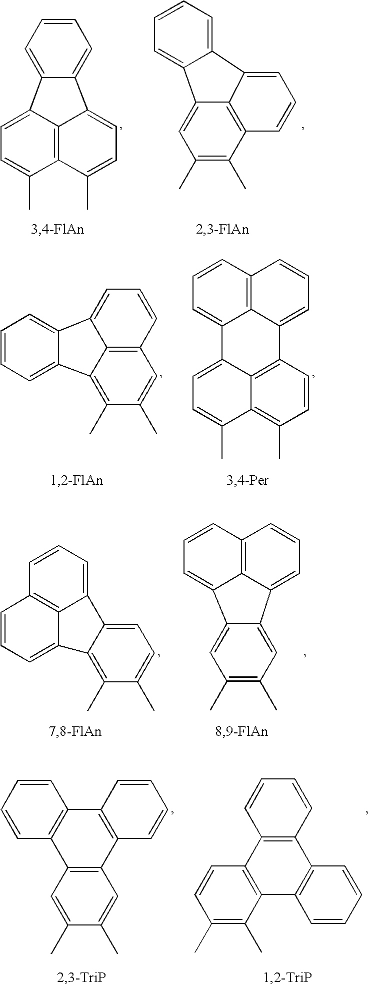
(where bonds that do not form a cycle indicate points of attachment), or ace, or indeno substituted derivatives; and substituents R₁ through R₉ excluding R₄ and R₈ are each individually hydrogen, silyl, alkyl of from 1 to 24 carbon atoms, substituted alkyl, aryl of from 5 to 30 carbon atoms, substituted aryl, fluorine or chlorine, heterocycle containing at least one nitrogen atom, or at least one oxygen atom, or at least one sulfur atom, or at least one boron atom, or at least one phosphorus atom, or at least one silicon atom, or any combination thereof.

Illustrative of useful amine compounds and their abbreviated names are those listed above for the first HTL and the following:
N,N′-bis(1-naphthalenyl)-N,N′-diphenylbenzidine (NPB);
N,N′-bis(1-naphthalenyl)-N,N′-bis(2-naphthalenyl)benzidine (TNB);
N,N′-bis(3-methylphenyl)-N,N′-diphenylbenzidine (TPD);
N,N′-Bis(N″,N ″-diphenylaminonaphthalen-5-yl)-N,N′-diphenyl-1,5-diaminonaphthalene (CAS 503624-47-3);
N,N′-Bis(4-methylphenylamine)-N,N′-diphenyl-1,4-phenylenediamine;
N,N′-Diphenyl-N,N′-di(m-tolyl)benzidine (CAS 65181-78-4);
N,N-Diphenylbenzidine (CAS 531-91-9);
N,N,N′,N′-Tetraphenylbenzidine (CAS 15546-43-7);
4-(2,2-Diphenylethen-1-yl)triphenylamine (CAS 89114-90-9);
N-(Biphenyl-4-yl)-N-(m-tolyl)aniline (CAS 154576-20-2);
N,N,N′,N′-Tetrakis(4-methylphenyl)benzidine (CAS 161485-60-5);
N,N′-Bis(4-methylphenyl)-N,N′-bis(phenyl)benzidine (CAS 20441-06-9);
N,N′,N″,N″′-Tetrakis(3-methylphenyl)-benzidine (CAS 106614-54-4);
N,N′-Di(naphthalene-1-yl)-N,N′-di(4-methylphenyl)-benzidine (CAS 214341-85-2);
N,N′-Di(naphthalene-2-yl)-N,N′-di(3-methylphenyl)benzidine (CAS 178924-17-9);
N,N′-Bis(4-methylphenyl)-N,N′-bis(phenyl)-1,4-phenylenediamine (CAS 138171-14-9);
1,1-Bis(4-bis(4-methylphenyl)aminophenyl)-cyclohexane (CAS 58473-78-2);
N,N,N′,N′-Tetrakis(naphthyl-2-yl)benzidine (CAS 141752-82-1);
N,N′-Bis(phenanthren-9-yl)-N,N′-diphenylbenzidine (CAS 141752-82-1);
N,N′-Bis(2-naphthalenyl)-N,N′-diphenylbenzidine (CAS 123847-85-8);
4,4′,4″-Tris(carbazol-9-yl)triphenylamine (CAS 139092-78-7);
N,N′-Bis(4-(2,2-diphenylethen-1-yl)phenyl)-N,N′-bis(phenyl)benzidine (CAS 218598-81-3);
N,N′-Bis(4-(2,2-diphenylethen-1-yl)phenyl)-N,N′-bis(4-methylphenyl)benzidine (CAS 263746-29-8);
N,N′-Bis(phenyl)-N,N′-bis(4′-(N,N-bis(naphth-1-yl)amino)biphenyl-4-yl)benzidine;
N,N′-Bis(phenyl)-N,N′-bis(4′-(N,N′-bis(phenylamino)biphenyl-4-yl)benzidine (CAS 167218-46-4);
Alpha Naphthylphenylbenzidine;
1,1-Bis[4-[N,N-di(p-tolyl)amino]phenyl]cyclohexane (CAS 58473-78-2);
1,4-Bis[2-[4-[N,N-di(p-tolyl)amino]phenyl]vinyl]benzene (CAS 55035-43-3);
1,3,5-Tri(9H-carbazol-9-yl)benzene (CAS 148044-07-9);
Tris(4-biphenylyl)amine (CAS 6543-20-0);
1,1-Bis(4-di-p-tolylaminophenyl)-4-phenylcyclohexane;
4,4′-Bis(diphenylamino)quadriphenyl;
Bis(4-dimethylamino-2-methylphenyl)phenylmethane;
4-(Di-p-tolylamino)-4′-[4-(di-p-tolylamino)styryl]stilbene;
Poly(N-vinylcarbazole);
4,4′- Bis[N-(1-naphthyl)-N-phenylamino]-p-terphenyl;
4,4′-Bis[N-(3-acenaphthenyl)-N-phenylamino]biphenyl;
4,4′-Bis[N-(9-anthryl)-N-phenylamino]biphenyl;
4,4′-Bis[N-(1-anthryl)-N-phenylamino]biphenyl;
4,4′-Bis[N-(2-perylenyl)-N-phenylamino]biphenyl;
2,6-Bis(di-p-tolylamino)naphthalene;
2,6-Bis[di-(1-naphthyl)amino]naphthalene;
2,6-Bis[N-(1-naphthyl)-N-(2-naphthyl)amino]naphthalene;
N,N,N′,N ′-Tetra(2-naphthyl)-4,4′-diamino-p-terphenyl;
4,4′-Bis[N-phenyl-N-(2-pyrenyl)amino]biphenyl;
2,6-Bis[N,N-di(2-naphthyl)amine]fluorine;
1,5-Bis[N-(1-naphthyl)-N-phenylamino]naphthalene;
7-Phenyl-7H-benz[k,l]acridine;
2,3,6,7-Tetrahydronaphtho[1,2,3-ij]quinolizine;
2,3,5,6,7,11,12,14,15,16-Decahydro-1H, 10H-anthra[1,2,3-ij:5,6,7-k′,j ′]diquinolizine;
N,N,N′,N′-Tetraphenylbenzo[x,y,z]heptaphene-6,9-diamine;
N,N′-Diphenylbenzo[x,y,z]heptaphene-6,9-diamine;
N,N′-Di-1-coronenyl-N,N′-diphenyl-[1,1′-biphenyl]-4,4′-diamine;
N,N′,N″-Tris[4-[2,2-bis(4-methylphenyl)ethenyl]phenyl]-N,N′,N″-tris(4-methylphenyl)-2,6,10-triphenylenetriamine;
4,4′-(6,12-Chrysenediyl)bis[N,N-bis(4-methylphenyl)]benzenamine;
N,N,N′,N′-Tetra-2-naphthalenyl-6, 1 2-chrysenediamine;
N,N′-Bis[4-(1,1-dimethylethyl)phenyl]-N,N′-diphenyl-6,12-chrysenediamine;
4,4′-(5,11-Chrysenediyldi-2,1-ethenediyl)bis[N,N-diphenylbenzenamine];
N-(7, 10-Diphenyl-3-fluoranthenyl)-N,7,10-triphenyl-3-fluoranthenamine;
N,N′-Bis[4-[2,2-bis(4-methylphenyl)ethenyl]phenyl]-N,N′-bis(4-methylphenyl)-3,8-fluoranthenediamine;
8-(9H-Carbazol-9-yl)-N,N-diphenyl-3-fluoranthenamine;
N,N-Bis(4-methylphenyl)-2-pyrenamine;
3-(1-Pyrenyl)-N,N-bis[3-(1-pyrenyl)phenyl]-benzenamine;
N,N′-[(9,9-Dimethyl-9H-fluorene-2,7-diyl)di-4,1-phenylene]bis[N-[4-(1,1-dimethylethyl)phenyl]-1-pyrenamine;
N,N-Bis([1,1′-biphenyl]-4-yl)-6,12-bis(1,1-dimethylethyl)-3-perylenamine;
N-[1,1′-Biphenyl]-3-yl-N-3-perylenyl-3-perylenamine;
N,N′-Di-2-naphthalenyl-N,N′-diphenyl-3,10-perylenediamine;
N,N′-(1,4-Naphthalenediyl-di-4,1-phenylene)bis[N-phenyl-3-perylenamine];
N-[4-(Diphenylamino)phenyl]-N-2-naphthacenyl-N′,N′-diphenyl-1,4-benzenediamine;
N-1-Naphthacenyl-N′-1-naphthalenyl-N-[4-(1-naphthalenylphenylamino)phenyl]-N′-phenyl-1,4-benzenediamine;
N-5-Naphthacenyl-N′-1-naphtbalenyl-N-[4-(1-naphthalenylphenyl-amino)phenyl]-N′-phenyl-1,4-benzenediamine;
N,N′-Diphenyl-N,N′-di-1H-pyrrol-2-yl-[1,1′-biphenyl]-4,4′-diamine;
Tris[4-(pyrrol-1-yl)phenyl]amine;
4,4′-[(1-Ethyl-1H-pyrrole-2,5-diyl)bis(4,1-phenylene-2,1-ethenediyl)]bis[N,N-diphenyl-benzenamine];
4-[2-(4-Methylphenyl)-2-(1H-pyrrol-2-yl)ethenyl]-N,N-bis[4-[2-(4-methylphenyl)-2-(1H-pyrrol-2-yl)ethenyl]phenyl]benzenamine;
N,N,N′,N′-Tetrakis(4-methoxyphenyl)-3,10-perylenediamine,
N,N,N′,N′,N″,N″,N″′,N″′-Octakis(4-methoxyphenyl)-1,4,7,10-perylenetetramine;
N-1-Naphthalenyl-N-[4′-(trifluoromethoxy)[1,1′-biphenyl]-2-yl]-3-perylenamine;
4,4′-(1,4-Naphthalenediyl-di-2,1-ethenediyl)bis[N-(4-methoxyphenyl)-N-phenyl-benzenamine;
N,N′-(Oxydi-4,1-phenylene)bis[N-methyl-3-perylenamine];
N-[4-(Diphenylamino)phenyl]-N-( 12-ethoxy-5-naphthacenyl)-N′,N′-diphenyl-1,4-benzenediamine;
N,N-Bis(4-phenoxyphenyl)-1-naphthacenamine;
2,2′-(1,4-Phenylene)bis[3-methoxy-N-9-phenanthrenyl-N-phenyl-6-benzofuranamine;
2,2′-(1,4-Phenylene)bis[N-1-naphthalenyl-N-phenyl-3-(trifluoromethyl)-6-benzofuranamine;
2,2′-(9,10-Anthracenediyl)bis[N-(3-methylphenyl)-N-phenyl-6-benzofuranamine;
N,N′-Diphenyl-N,N′-bis[4-(3-phenyl-2-benzofuranyl)phenyl]-[1,1′-biphenyl]-4,4′-diamine;
N,N′-bis[4′-[[8-[bis(2,4-dimethylphenyl)amino]-2-dibenzofuranyl](4-methylphenyl)amino][1,1′-biphenyl]-4-yl]-N,N′-bis(4-methylphenyl)-2,8-dibenzofurandiamine;
2,2′-( 1,4-Phenylene)bis[N,N-diphenyl-6-benzofuranamine;
N-2-Benzofuranyl-N′-[4-(2-benzofuranylphenylamino)phenyl]-N′-3-perylenyl-N-phenyl-1,4-benzenediamine;
N,N-Bis[4-(dimethylphenylsilyl)phenyl]-3-perylenamine;
4-(Triphenylsilyl)-N,N-bis[4-(triphenylsilyl)phenyl]-benzenamine;
4-(Dimethylphenylsilyl)-N,N-bis[4-(dimethylphenylsilyl)phenyl]-benzenamine;
N,N-Bis[4-(dimethyl-2-naphthalenylsilyl)phenyl]-4-ethoxy-benzenamine;
4,4′-(9,10-Anthracenediyl)bis[N,N-bis[4-(methyldiphenylsilyl)phenyl]-benzenamine;
N,N-Bis[4′-[bis[4-(methyldiphenylsilyl)phenyl]amino][1,1′-biphenyl]-4-yl]-N′,N′-bis[4-(methyldiphenylsilyl)phenyl]-[1,1′-biphenyl]-4,4′-diamine;
N,N,N′,N′-Tetrakis[4-(diphenylphosphino)phenyl]-[1,1′-biphenyl]-4,4′-diamine;
4,4′-(9,10-Anthracenediyl)bis[N,N-bis[4-[bis(4-methylphenyl)-phosphino]phenyl]-benzenamine;
4,4′-(9,10-anthracenediyl)bis[N,N-bis[4-(diphenylphosphinyl)phenyl]-benzenamine; or
4,4′-(9,10-Anthracenediyl)bis[N,N-bis[4-(diphenylphosphino)phenyl]-benzenamine.

In one embodiment of the present invention, both the first material and the second material include an amine compound. In another useful embodiment, the first material includes a compound incorporating a para-phenylenediamine, dihydrophenazine, 2,6-diaminonaphthalene, 2,6-diaminoanthracene, 2,6,9,10-tetraaminoanthracene, anilinoethylene, N,N,N,N-tetraarylbenzidine, mono- or polyaminated perylene, mono- or polyaminated coronene, polyaminated pyrene, mono- or polyaminated fluoranthene, mono- or polyaminated chrysene, mono- or polyaminated anthanthrene, mono- or polyaminated triphenylene, or mono- or polyaminated tetracene moiety while the second material includes an amine compound that contains either a N,N,N,N-tetraarylbenzidine or a N-arylcarbazole moiety.

Light-Emitting Layer(s)

According to the present invention, the light-emitting layer(s) (either layer 232 of FIG. 2 or layer 333 of FIG. 3) is (are) primarily responsible for the electroluminescence emitted from the OLED device. One of the most commonly used formulations for the light-emitting layer is an organic thin film including at least one host and at least one dopant. The host serves as the solid medium or matrix for the transport and recombination of charge carriers injected from the HTL and the ETL. The dopant, usually homogeneously distributed within the host in small quantity, provides the emission centers where excitons are collected and light is produced. Based on the teaching of the prior art such as above cited, commonly-assigned U.S. patent application Ser. No. 10/889,654, the present invention uses a light-emitting layer including a host and a dopant and a hole-trapping material, where the hole-trapping material is added to the light-emitting layer at concentrations that enable it to serve as a hole-trapping agent and not as a hole-conducting agent. Therefore, the concentration of the hole-trapping material should be less than about 15%, preferably less than 10% and even more preferably less than 5% by weight, which leads to significant increases in electroluminescent efficiency. A distinguishing feature of the present invention over the prior art is that it uses specific HTL's as described above and ETL's, which are described below and allow for further significant increases in the electroluminescent efficiency. Another distinguishing feature of the present invention over the prior art is that it relates to the light-emitting layers of all colors, from violet to deep red. Another distinguishing feature of the present invention over the prior art is that it provides a range for useful oxidation potentials or Highest Occupied Molecular Orbital (HOMO) levels for all of the HTL and LEL components. The selection of the components of the light-emitting layer(s), that is the host, the dopant, and the hole-trapping material, is in accordance with the following criteria:

1) The hole-trapping material is provided to be 0.1 to less than 15% by volume relative to its corresponding LEL volume to serve as a hole-trapping agent and specifically not as a hole-transport component;

2) The oxidation potential for the hole-trapping material is in a range of from +0.4 to +1.1 V vs. SCE and is selected so that it is less than the oxidation potential of its corresponding host by at least 0.1 V (or the HOMO level for the hole-trapping material is closer to the vacuum level by at least 0.1 eV compared to the HOMO level of its corresponding host) in order to serve as a hole trap;

3) The oxidation potential for the hole-trapping material is further selected so as to avoid formation of a harmful charge transfer complex between the hole-trapping material and the host. A harmful charge transfer complex would be one whose electronic energy for the first singlet excited state is lower than the electronic energy for the emissive excited state of the dopant. This would reduce the EL efficiency of the dopant and of the entire device. Furthermore, if the charge transfer complex is emissive itself then the electroluminescent color would change;

4) The oxidation potential for the hole-trapping material is further selected so as to avoid formation of a harmful charge transfer complex between the hole-trapping material and the dopant. A harmful charge transfer complex would be one whose electronic energy for the first singlet excited state is lower than the electronic energy for the emissive excited state of the dopant. This would alter the emissive properties of the dopant and reduce the EL efficiency of the dopant and of the entire device, and change the electroluminescent color;

5) If the electroluminescent color of the inventive OLED device is intended to be blue or blue-green and thus a blue-emitting or blue-green-emitting dopant is chosen, the oxidation potential for the hole-trapping material should not be so low as to cause formation of a harmful charge transfer complex between the hole-trapping material and the host. If the electroluminescent color of the inventive OLED device is intended to be green, yellow, orange or red and, thus, a dopant of appropriate emission color is chosen, the oxidation potential of the hole-trapping material may be so low as to cause formation of a useful charge transfer complex between the hole-trapping material and the host, although formation of such useful charge-transfer complex is not required to practice the current invention but may be simply coincidental. The electronic energy for the first singlet excited state of such a useful charge-transfer complex should be higher than the electronic energy for the emissive excited state of the dopant, and the charge-transfer complex should be able to efficiently donate electronic excitation energy to the dopant, so that the charge transfer complex would not reduce the EL efficiency of the dopant and the electroluminescent efficiency of the device would still be improved. For OLED devices of any color, the oxidation potential of the hole-trapping material should not be so low as to cause formation of a harmful charge transfer complex between the hole-trapping material and the dopant, which more than likely would reduce the EL efficiency of the dopant and of the entire device;

6) The energy of the lowest singlet excited electronic state of the hole-trapping material should be larger than that for the fluorescent dopant. The energy of the lowest triplet electronic state of the hole-trapping material should be larger than that for the phosphorescent dopant. Otherwise the hole-trapping material would reduce the EL efficiency of the dopant and of the entire device;

7) The hole-trapping material- should be able to efficiently donate electronic excitation energy to the dopant otherwise the hole-trapping material may reduce the electroluminescent efficiency of the dopant and of the entire device;

8) The host of the light-emitting layer is selected to include at least one organic material, which is capable of carrying both hole and electron current, injected from the hole-transport and electron-transport layers, respectively, and which has an oxidation potential of +1.0 V or higher vs. SCE, and has a peak emission wavelength at 475 nm or shorter, and which when mixed with the hole-trapping material forms a continuous and substantially pin-hole-free layer; and

9) The dopant is a highly luminescent organic compound or a highly luminescent organometallic complex, which provides the emission centers where excitons are collected and colored light is produced. The energy of the lowest singlet excited electronic state for the fluorescent dopant should be smaller than that of each of the following: the second material (the one that composes the second HTL), the host, and the hole-trapping material. The energy of the lowest triplet electronic state for the phosphorescent dopant should be smaller than that of each of the following: the second material, the host, and the hole-trapping material.

Peak emission wavelength is most appropriately measured by known procedures to those skilled in the art using photo-excitation of a thermally evaporated solid film.

Electrochemical oxidation potentials can be measured by known procedures to those skilled in the art, for example, as described by J. Wang in Analytical Electrochemistry, 2^{nd} Edition, 2000, Wiley-VCH, or for OLED materials as described by C. Schmitz, H. Schmidt, and H. W. Thelakkat in Chem. Mat. 2000, 12, 3012-3019 (HOMO levels can be measured by known procedures to those skilled in the art, traditionally using ultra-violet photon spectroscopy, UPS). For example, in accordance with the requirements of this invention, the oxidation potential for a hole-trapping material, in particular amines, should be in a range of from +0.4 to +1.5 V vs. SCE (saturated calomel electrode) for the material to be useful in OLEDs (of any color) that utilize wide optical bandgap host materials (optical bandgap is difference in energy between the ground electronic state and excited electronic state—singlet bandgap for the case of fluorescent devices and triplet bandgap for the case of phosphorescent devices) having oxidation potentials as low as +1.6 V. Furthermore, the preferable range is +0.6 to +1.1 V vs. SCE for the hole-trapping material, in particular amines, to be useful in blue and blue-green OLEDs using anthracene derivatives, in particular hydrocarbon 9,10-disubstituted anthracenes, with oxidation potentials of +1.2 V or higher as hosts. For green and red OLEDs, the lower limit of the oxidation potential range for an amine additive could be lowered to +0.4 V and +0.2 V, respectively.

In accordance with this invention, a charge transfer complex can be understood as an electron donor—electron acceptor complex, whose physical and chemical properties are different from those for the separate components that come together to form the complex, and in which there is a donor molecule and an acceptor molecule as described by J. March and M. B. Smith in Advanced Organic Chemistry, 5^{th} Ed., pp. 102-104, 2001, John Wiley & Sons. The donor can donate an unshared pair or pair of electrons in an orbital of a double bond or aromatic system. One test for the presence of a charge transfer complex is the electronic spectrum. The complex generally exhibits a spectrum (called a charge transfer spectrum) that is not the same as the sum of the spectra of the two individual components. In most charge transfer complexes, the donor and acceptor molecules are present in an integral ratio, most often 1:1, but complexes with nonintegral ratios are also known. In accordance with this invention for the cases of blue and blue-green OLEDs, the electronic spectrum of the mixture of hole-trapping material, host, and dopant is identical to the sum of the individual components, thus indicating an absence of a harmful charge transfer complex between the hole-trapping material and the host, or dopant, which would quench the electroluminescence efficiency of the dopant. However, for green, yellow, orange, red, and white OLEDs, formation of the charge transfer complex between the host and the hole-trapping material is allowable (but not necessary) as long as (i) the electronic energy for the first singlet excited state of the charge-transfer complex is higher than the electronic energy for the emissive excited state of the dopant, and (ii) the charge-transfer complex is able to donate its excitation energy to the dopant (for example, the complex should be luminescent, that is have a substantial quantum yield of luminescence). This would ensure that the emission color of the light-emitting layer and its EL efficiency are characteristic of the green, yellow, orange, or red dopant.

Note, that the device of the present invention may include more than one LEL, having the same materials in each LEL but at different concentrations, for example having relatively more of the hole-trapping material in an LEL which is closer to the anode, and relatively less of the hole-trapping material in an LEL which is closer to the cathode. On the other hand, different LELs may be constructed using different hosts, dopants, and hole-trapping materials and these LELs can either produce the light of the same color or of different colors.

Light-emitting layer(s): hole-trapping materials

The hole-trapping materials which embody this invention include the class of amines and more specifically include the classes of mono-, di-, and triarylamines, mixed alkyl(aryl)amines, mono-, di, and trialkylamines, aminobenzenes, styrylamines, bis-styrylamines, aminoanthracenes, aminotetraphenes, amino-oligophenylenes, aminofluorenes, aminocoronenes, aminotriphenylenes, aminophenanthrenes, aminonaphthalenes, aminochrysenes, aminofluoranthenes, aminopyrenes, aminoperylenes, and aminotetracenes. It is understood that the energy for the appropriate electronically excited state of an amine should be higher than that for the fluorescent or phosphorescent dopant. It is also to be understood that other hole-trapping materials, for example, other nitrogen atom containing compounds, such as pyrroles, silicon atom containing compounds, phosphorous atom containing compounds, oxygen atom containing compounds, and sulfur atom containing compounds, can be used in the same manner as amines to impart improved efficiency as described in this invention, as long as they satisfy the abovementioned criteria of hole-trapping (have suitable oxidation potential and HOMO level) and proper excitation energy cascade that ensures exciton placement on the luminescent dopant. Thus, for example, the hole-trapping material for a blue or blue-green light-emitting layer containing a host with oxidation potential +1.2 V or higher may include:
i) an alkyl, alkoxy, aryl, or aryloxy derivative of pyrrole with oxidation potential, in a range of from +0.5 to +1.2 V vs. SCE;
ii) a mono or poly-substituted alkoxy or aryloxy derivative of an aromatic hydrocarbon compound with the oxidation potential in a range of from +0.5 to +1.2 V vs. SCE;
iii) an alkyl, alkoxy, aryl, or aryloxy derivative of furan with the oxidation potential in a range of from +0.5 to +1.2 V vs. SCE;
iv) an alkyl or aryl derivative of silane with the oxidation potential in a range of from +0.5 to +1.2 V vs. SCE;
v) an alkyl or aryl derivative of phosphine with the oxidation potential in a range of from +0.5 to +1.2 V vs. SCE;
vi) an alkylsulfide or arylsulfide with the oxidation potential in a range of from +0.5 to +1.2 V vs. SCE; or
vii) or an alkyl, alkoxy, aryl, or aryloxy derivative of thiophene with the oxidation potential in a range of from +0.5 to +1.2 V vs. SCE.

A class of materials useful as the hole-trapping materials includes amine compounds (described above) Illustrative of useful amine compounds are the amine compounds given above for the second HTL and the first HTL.

Another illustrative class of materials useful as hole-trapping materials includes structures having an alkyl or aryl moiety containing a sulfur atom or atoms including the following:
4,4′-(1E)-1,2-Ethenediylbis[N,N-bis[4-[(1E)-2-[4-[bis[4-(butylthio)phenyl]amino]phenyl]ethenyl]phenyl]-benzenamine;
N,N-Bis[3-[[3-(diphenylamino)phenyl]thio]phenyl]-3-perylenamine;
3,4,9,10-Tetraphenyl-N,N,N′,N′-tetrakis[4-(phenylsulfonyl)phenyl]-1,7-perylenediamine;
4,4′-(1,2-Ethenediyl)bis[N,N-bis[4-(phenylthio)phenyl]-1-naphthalenamine;
6,11-Dimethyl-N,N-bis[4-(phenylsulfonyl)phenyl]-2-naphthacenamine;
N,N-Bis[4-(phenylthio)phenyl]-2-naphthacenamine;
10,10′-(2,5-Thiophenediyl)bis[N,N-bis[4-(phenylsulfonyl)phenyl]-9-anthracenamine;
2,2′-(1,4-phenylene)bis[N-1-naphthalenyl-N-phenyl-benzo[b]thiophen-6-amine;
N,N-Bis[4-(2-thienyl)phenyl]-3-perylenamine;
5-[4-(Diphenylamino)phenyl]-N-[5-[4-(diphenylamino)phenyl]-2-thienyl]-N-3-perylenyl-2-thiophenamine;
N-3-perylenyl-5-phenyl-N-(5-phenyl-2-thienyl)-2-thiophenamine; or
N-[2,2′-Bithiophen]-5-yl-N-3-perylenyl-[2,2′-bithiophen]-5-amine.

Another illustrative class of materials useful as hole-trapping materials includes structures having a pyrrole moiety including the following:

2-[4-(8-Fluoranthenyl)-3-(9-phenanthrenyl)phenyl]-1-phenyl-1H-pyrrole, or

2-(3,4-Di-9-phenanthrenylphenyl)-1H-pyrrole.

Another illustrative class of materials useful as hole-trapping materials includes structures having an aryloxy-or alkoxy-substituted moiety including the following:
1,2,3,4-Tetra(p-methoxyphenyl)naphthalene; or
3,8,11,16-Tetramethoxy-perylo[3,2,1,12-pqrab]perylene.

Light-Emitting Layer(s): Hosts

Materials for the host of the light-emitting layer of the present invention include organic compounds that are capable of carrying both positive and negative electrical charges and, when mixed with the hole-trapping material, are capable of forming a continuous and substantially pin-hole-free thin film. They can be polar, such as (i) the blue AlQ (“BAlQ”) class of compounds for blue, blue-green, green, yellow, orange, and red OLEDs, and other similar oxinoid and oxinoid-like compounds and metal complexes, and (ii) the compounds of the heterocyclic family for blue, blue-green, green, yellow, orange, and red OLEDs, such as those based on oxadiazole, imidazole, pyridine, phenanthroline, triazine, triazole, quinoline, and other moieties. They also can be nonpolar, such as (i) the anthracene class of compounds for blue, blue-green, green, yellow, orange, and red OLEDs, such as 2-(1,1-dimethylethyl)-9,10-bis(2-naphthalenyl)anthracene (TBADN), 9,10-Bis[4-(2,2-diphenylethenyl)phenyl]anthracene, and 10,10′-Diphenyl-9,9′-bianthracene, (ii) the compounds of the triarylamine family for blue, blue-green, green, yellow, orange, and red OLEDs, such as NPB, TNB, and TPD, (iii) the compounds of the carbazole family for blue, blue-green, green, yellow, orange, and red OLEDs, such as CBP and TCTA, (iv) the compounds of the styryl family for blue, blue-green, green, yellow, orange, and red OLEDs, such as DPVBi, and (v) the compounds of the fluorene family for blue, blue-green, green, yellow, orange, and red OLEDs.

A necessary condition is that the hole-trapping material must be able to trap holes within the matrix of the host component. This property is characterized by the oxidation potentials (Eₒₓ) or HOMO levels of the hole-trapping material and the host. Another necessary condition is that the host should have a peak emission wavelength at 475 nm or shorter. Another necessary condition is that the energy of the emissive electronic state for the luminescent dopant should be smaller than the energy of the corresponding (lowest excited singlet or lowest triplet) electronic state of each of the following: the hole-trapping material and the host. This ensures that electronic excitation energy transfer from the hole-trapping material and the host, resulting from the recombination of electrons and holes in the hole-trapping material and host, to the light-producing dopant is favorable. Another necessary condition is that no harmful charge-transfer complexes are formed between the hole-trapping material and the host and the hole-trapping material and the dopant.

The first preferred class of materials useful as the host includes anthracene compounds, that is, structures having an anthracene moiety. Exemplary of contemplated anthracene compounds are those satisfying the following structural formula: 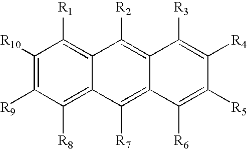
wherein:
substituents R₂ and R₇ are each individually and independently alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; and substituents R₁ through R₁₀ excluding R₂ and R₇ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₀ substituents excluding R₂ and R₇ form an annelated benzo-, naphtho-, anthra-, phenanthro-, fluorantheno-, pyreno-, triphenyleno-, or peryleno-substituent or its alkyl or aryl substituted derivative; or any two adjacent R₁ through R₁₀ substituents excluding R₂ and R₇ form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative; R₂ and R₇ independently represents a naphthyl or biphenyl group; R₂ and R₇ independently represent a naphthyl or biphenyl group and R₁, R₃, R₄, R₅, R₆, R₈, R₉, or R₁₀ independently represents an aromatic group.

Illustrative of useful anthracene compounds and their abbreviated names are the following:
2-(1,1-dimethylethyl)-9,10-bis(2-naphthalenyl)anthracene (TBADN);
9,10-bis(2-naphthalenyl)anthracene (AND);
9,10-bis(6-cyano-2-naphthalenyl)anthracene (AND(CN)₂);
9-biphenyl-10-(2-naphthalenyl)anthracene (BPNA);
9,10-bis(1-naphthalenyl)anthracene;
9,10-Bis[4-(2,2-diphenylethenyl)phenyl]anthracene;
9,10-Bis([1.1′:3′,1″-terphenyl]-5′-yl)anthracene;
9,9′-Bianthracene;
10,10′-Diphenyl-9,9′-bianthracene (Ph₂A₂);
10,10′-Bis([1,1′:3′,1″-terphenyl]-5′-yl)-9,9′-bianthracene;
2,2′-Bianthracene;
9,9′,10,10′-Tetraphenyl-2,2′-bianthracene (2,2′DPA₂);
9,10-Bis(2-phenylethenyl)anthracene;
9-Phenyl-10-(phenylethynyl)anthracene;
9,9′,9″-(1,3,5-Benzenetriyl)tris[10-(9-phenanthrenyl)-anthracene;
1,1′-[5-[10-(4-Methoxyphenyl)-9-anthracenyl]-1,3-phenylene]bis-pyrene;
1,1′-(9,10-Anthracenediyldi-4,1-phenylene)bis-pyrene;
9,10-Bis[3-(9-phenanthrenyl)phenyl]-anthracene;
9-[5-(9-Phenanthrenyl)[1,1′-biphenyl]-3-yl]-10-phenyl-anthracene;
2-(1,1-Dimethylethyl)-9,10-di-9-phenanthrenyl-anthracene;
7-(p-9-Anthrylphenyl)-benz[a]anthracene;
3-[4-[10-(3-Fluoranthenyl)-9-anthracenyl]phenyl]-fluoranthene;
3-[10-[4-(2-Naphthalenyl)phenyl]-9-anthracenyl]-fluoranthene;
3-[4-[10-(2Naphthalenyl)-9-anthracenyl]phenyl]-fluoranthene;
3,3′-(9,10-Anthracenediyl)bis[8,11-diphenyl-benzo[k]fluoranthene; or
3,3′-(9,10-Anthracenediyl)bis[7,12-di-1-naphthalenyl-benzo[k]fluor-anthene.

Another preferred class of materials as the host is the oxinoid compounds. Exemplary of contemplated oxinoid compounds are those satisfying the following structural formula: 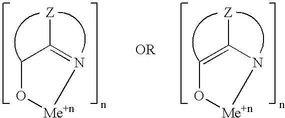
wherein:
Me represents a metal;
n is an integer of from 1 to 3; and
Z independently in each occurrence represents the atoms completing a nucleus having at least two fused aromatic rings.

From the foregoing it is apparent that the metal can be monovalent, divalent, or trivalent metal. The metal can, for example, be an alkali metal, such as lithium, sodium, rubidium, cesium, or potassium; an alkaline earth metal, such as magnesium, strontium, barium, or calcium; or an earth metal, such as boron or aluminum, gallium, and indium. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is preferably maintained at 18 or less.

The list of oxinoid compounds further includes metal complexes with two bi-dentate ligands and one mono-dentate ligand, for example Al(2-MeQ)₂(X) where X is any aryloxy, alkoxy, arylcaboxylate, and heterocyclic carboxylate group. For example, a bis(8-quinolinolato)(phenolate)aluminum(III) chelate below:
(R′—Q)₂—Al—O—L
wherein:
Q in each occurrence represents a substituted 8-quinolinolato ligand;
R′ represents an 8-quinolinolato ring substituent chosen to block sterically the attachment of more than two substituted 8-quinolinolato ligands to the aluminum atoms;
O—L is a arylolato ligand; and
L is a hydrocarbon group that includes an aryl moiety.

Illustrative of useful chelated oxinoid compounds and their abbreviated names are the following:
Bis(8-quinolinol)magnesium (MgQ₂);
8-Quinolinol lithium (LiQ);
Bis(10-hydroxybenzo[h]quinolinato)beryllium(BeBq₂);
Bis(2-Methyl-8-quinolinol)magnesium (Mg(2-MeQ)₂);
Bis(2-methyl-8-quinolinolato)(4-phenylphenolato)aluminum(III) (BAlQ);
Bis(2-methyl-8-quinolinolato)phenolato)aluminum(III);
Bis(2-methyl-8-quinolinolato)ortho-cresolato)aluminum(III);
Bis(2-methyl-8-quinolinolato)(meta-cresolato)aluminum(III);
Bis(2-methyl-8-quinolinolato)(para-cresolato)aluminum(III);
Bis(2-methyl-8-quinolinolato)(ortho-phenylphenylato)aluminum (III);
Bis(2-methyl-8-quinolinolato)(meta-phenylphenylato)aluminum(III);
Bis(2-methyl-8-quinolinolato)(2,3-dimethyl-phenylato)aluminum(III);
Bis(2-methyl-8-quinolinolato)(2,6-dimethyl-phenylato)aluminum(III);
Bis(2-methyl-8-quinolinolato)(3,4-dimethyl-phenolato)aluminum(III);
Bis(2-methyl-8-quinolinolato)(3,5-dimethyl-phenolato)aluminum(III);
Bis(2-methyl-8-quinolinolato)(2,3-di-tert-butyl-phenolato)aluminum(III);
Bis(2-methyl-8-quinolinolato)(2,6-diphenyl-phenolato)-aluminum(III);
Bis(2-methyl-8-quinolinolato)(2,4,6-triphenyl-phenolato)aluminum(III);
Bis(2-methyl-8-quinolinolato)(2,3,6-trimethyl-phenolato)aluminum(III);
Bis(2-methyl-8-quinolinolato)(2,3,5,6-tetramethyl-phenolato)-aluminum(III);
Bis(2-methyl-8-quinolinolato)(1-naphtholato)aluminum(III);
Bis(2-methyl-8-quinolinolato)(2-naphtholato)aluminum(III);
Bis(2,4-dimethyl-8-quinolinolato)(2-phenylphenolato)aluminum(III);
Bis(2,4-dimethyl-8-quinolinolato)(4-phenylphenolato)aluminum(III);
Bis(2,4-dimethyl-8-quinolinolato)(3-phenylphenolato)aluminum(III);
Bis(2,4-dimethyl-8-quinolinolato)(3,5-dimethyl-phenolato)aluminum(III); or
Bis(2,4-dimethyl-8-quinolinolato)(3,5-di-tert-butyl-phenolato)-aluminum(III).

Another class of materials useful as the host includes fluorene compounds, that is, structures having a fluorene moiety. Exemplary of contemplated fluorene compounds are those satisfying the following structural formula: 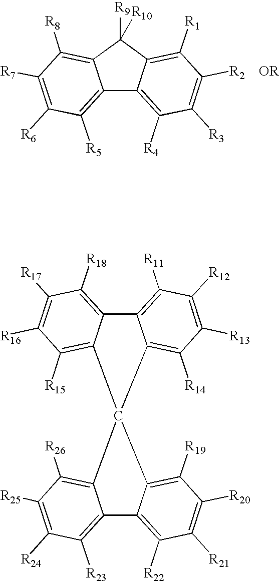
wherein:
substituents R₁ through R₂₅ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₂₅ substituents excluding R₉ and R₁₀ form an annelated benzo-, naphtho-, anthra-, phenanthro-, fluorantheno-, pyreno-, triphenyleno-, or peryleno-substituent or its alkyl or aryl substituted derivative; or any two R₁ through R₂₅ substituents excluding R₉ and R₁₀ form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative.

Illustrative of useful fluorene compounds and their abbreviated names are the following:
2,2′,7,7″-Tetraphenyl-9,9′-spirobi[9H-fluorene];
2,2′,7,7′-Tetra-2-phenanthrenyl-9,9′-spirobi[9H-fluorene];
2,2′-Bis (4-N,N-diphenylaminophenyl)-9,9′-spirobi[9H-fluorene] (CAS 503307-40-2);
4′-Phenyl-spiro[fluorene-9,6′-[6H]indeno[1,2-j]fluoranthene];
2,3,4-Triphenyl-9,9′-spirobifluorene;
11,11′-Spirobi[11H-benzo[b]fluorene];
9,9′-Spirobi[9H-fluorene]-2,2′-diamine;
9,9′-Spirobi[9H-fluorene]-2,2′-dicarbonitrile;
2′,7′-Bis([1,1′-biphenyl]-4-yl)-N,N,N′,N′-tetraphenyl-9,9′-spirobi[9H-fluorene]-2,7-diamine;
9,9,9′,9′,9″,9″-Hexaphenyl-2,2′:7′,2″-ter-9H-fluorene;
2,7-Bis([1,1′-biphenyl]-4-yl)-9,9′-spirobi [9H-fluorene];
2,2′,7,7′-tetra-2-Naphthalenyl-9,9′-spirobi[9H-fluorene]; or
9,9′-[(2,7-Diphenyl-9H-fluoren-9-ylidene)di-4,1-phenylene]bis-anthracene.

Another class of materials useful as the host includes heterocyclic benzenoid compounds, such as those based on oxadiazole, imidazole, benzimidazole, pyridine, phenanthroline, triazine, triazole, quinoline and other moieties. These structures may include benzoxazolyl, and thio and amino analogs of benzoxazolyl of the following general molecular structure: 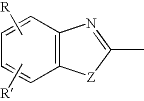
wherein:
Z is O, NR″ or S; R and R′, are individually hydrogen, alkyl of from 1 to 24 carbon atoms, aryl or hetero-atom substituted aryl of from 5 to 20 carbon atoms, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or atoms necessary to complete a fused aromatic ring; and R″ is hydrogen; alkyl of from 1 to 24 carbon atoms; or aryl of from 5 to 20 carbon atoms. These structures further include alkyl, alkenyl, alkynyl, aryl, substituted aryl, benzo-, naphtho-, anthra-, phenanthro-, fluorantheno-, pyreno-, triphenyleno-, or peryleno-, 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, indeno, fluoro, cyano, alkoxy, aryloxy, amino, aza, heterocyclic, keto, or dicyanomethyl derivatives thereof.

Another class of materials useful as the host includes carbazole compounds, such as those represented by: 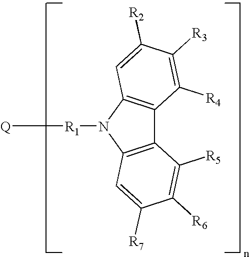
wherein:
Q independently represents nitrogen, carbon, an aryl group, or substituted aryl group, preferably a phenyl group;
R₁ is preferably an aryl or substituted aryl group, and more preferably a phenyl group, substituted phenyl, biphenyl, substituted biphenyl group;
R₂ through R₇ are independently hydrogen, alkyl, phenyl or substituted phenyl group, aryl amine, carbazole, or substituted carbazole; and
n is selected from 1 to 4.

Another useful class of carbazole compounds satisfies the following structural formula: 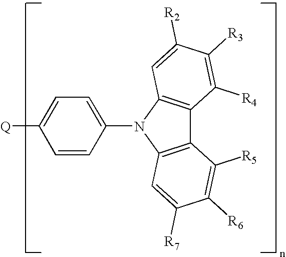
wherein:
n is an integer from 1 to 4;
Q is nitrogen, carbon, an aryl, or substituted aryl;
R₂ through R₇ are independently hydrogen, an alkyl group, phenyl or substituted phenyl, an aryl amine, a carbazole and substituted carbazole.

Illustrative of useful substituted carbazole compounds are the following:
4-(9H-carbazol-9-yl)-N,N-bis[4-(9H-carbazol-9-yl)phenyl]-benzenamine (TCTA);
4-(3-phenyl-9H-carbazol -9-yl)-N,N-bis[4(3-phenyl-9H-carbazol-9-yl)phenyl]-benzenamine;
9,9′-[5′-[4-(9H-carbazol-9-yl)phenyl][1,1′:3′,1″-terphenyl]-4,4″-diyl]bis-9H-carbazole.

In one suitable embodiment the carbazole compounds satisfy the following formula: 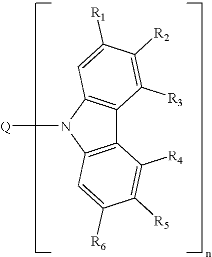
wherein:
n is selected from 1 to 4;
Q independently represents phenyl group, substituted phenyl group, biphenyl, substituted biphenyl group, aryl, or substituted aryl group;
R₁ through R₆ are independently hydrogen, alkyl, phenyl or substituted phenyl, aryl amine, carbazole, or substituted carbazole.

Examples of suitable materials are the following:
9,9′-(2,2′-dimethyl [1,1′-biphenyl]-4,4′-diyl)bis-9H-carbazole (CDBP);
9,9′-[1,1′-biphenyl]-4,4′-diylbis-9H-carbazole (CBP);
9,9′-(1,3-phenylene)bis-9H-carbazole (mCP);
9,9′-(1,4-phenylene)bis-9H-carbazole;
9,9′,9″-(1,3,5-benzenetriyl)tris-9H-carbazole;
9,9′-(1,4-phenylene)bis[N,N,N′,N′-tetraphenyl-9H-carbazole-3,6-diamine;
9-[4-(9H-carbazol-9-yl)phenyl]-N,N-diphenyl-9H-carbazol-3-amine;
9,9′-(1,4-phenylene)bis[N,N-diphenyl-9H-carbazol-3-amine;
9-[4-(9H-carbazol-9-yl)phenyl]-N,N,N′,N′-tetraphenyl-9H-carbazole-3,6-diamine.

Another class of materials useful as the host includes styryl compounds, such as
4,4′-bis(2,2-diphenylethenyl)-1,1′-biphenyl (DPVBi);
4,4′-bis(triphenylethenyl)-1,1′-biphenyl;
4,4″-bis(2,2-diphenylethenyl)-1,1′:4′,1″-terphenyl,
1,1′-(1,2-ethenediyl)bis[4-(2,2-diphenylethenyl)benzene;
4,4′-bis(2,2-diphenylethenyl)-1,1′-binaphthalene; or
analogous compounds.

Another class of materials useful as the host includes amine compounds (as described above).

Light-Emitting Layer(s): Dopants

The dopant is usually chosen from highly fluorescent dyes, but phosphorescent compounds, e.g., transition metal complexes as described in WO 98/55561, WO 00/18851, WO 00/57676, and WO 00/70655 are also useful. The material selection criteria for the dopant in the light-emitting layer are (1) the dopant has a high efficiency of fluorescence or phosphorescence in the matrix of the host and the hole-trapping material, and (2) the energy of the emissive electronic state for the luminescent dopant is smaller than the energy of the corresponding (lowest excited singlet or lowest triplet) electronic state of each of the following: the second material (the one that composes the second HTL), the host, and the bole-trapping material.

For blue-emitting OLEDs, a preferred class of dopants for this invention includes perylene compounds: 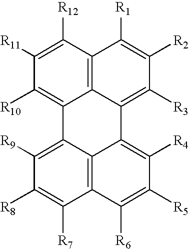
wherein:
substituents R₁ through R₁₂ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24-carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₂ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₂ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative.

These materials possess fluorescence efficiencies as high as unity in solutions. Representative materials of this class include:
Perylene;
2,5,8,11-Tetra-tert-butylperylene (TBP);
2,8-Di-tert-Butylperylene;
Ovalene;
Dibenzo[b,ghi]perylene; or
Dibenzo[b,k]perylene.

For blue-emitting OLEDs, another preferred class of dopants for this invention includes aza-dipyridinomethene borate (ADPMB) compounds: 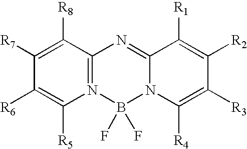
wherein:
substituents R₁ through R₈ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₈ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₈ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative.

These materials possess fluorescence efficiencies as high as unity in solutions. Representative materials of this class include:

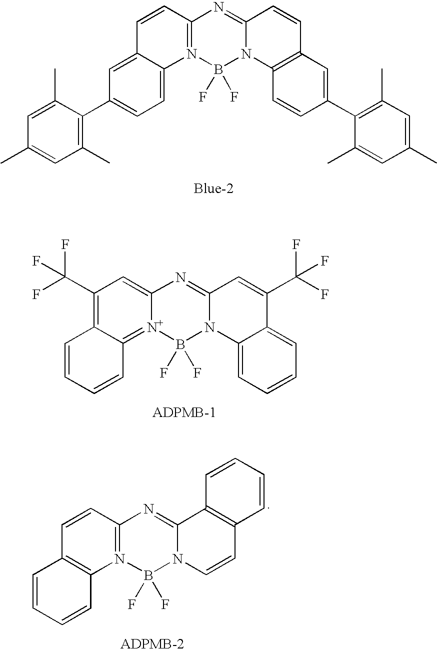

For blue- or blue-green emitting OLEDs, another preferred class of dopants for this invention includes DHMB borate compounds: 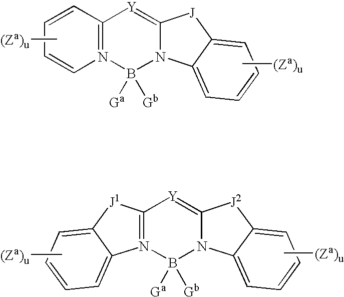
wherein:
substituents Z^{a} are each individually fluoro, cyano, alkoxy, aryloxy, diarylamino, arylalkylamino, dialkylamino, trialkylsilyl, triarylsilyl, diarylalkylsilyl, dialkylarylsilyl, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent Z^{a} substituents form an annelated benzo-, naphtho-, anthra-, phenanthro-, fluorantheno-, pyreno-, triphenyleno-, or peryleno-substituent or its alkyl or aryl substituted derivative; each u independently is 0-4; Y represents N or C—X, wherein X represents hydrogen, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; G^{a} and G^{b} represent independently halogen, alkyl, aryl, alkoxy, arylthio, sulfamoyl, acetamido, diarylamino, aryloxy, fluoro, or alkyl carboxylate; J, J¹ and J² independently represents O, S, Se, or N-A, wherein A represents alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof.

These materials possess fluorescence efficiencies as high as unity in solutions. Representative materials of this class include:

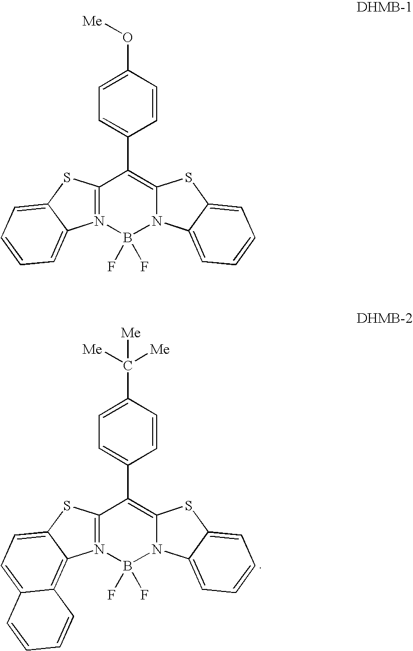

For green-blue, blue-green, and blue-emitting OLEDs, another preferred class of dopants for this invention includes bisaminostyrylarene (BASA) compounds: 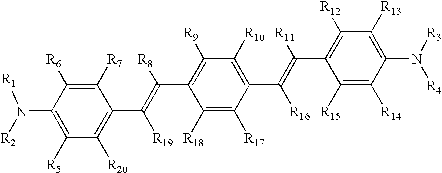
wherein:
each double bond can be either E or Z independently of the other double bond; substituents R₁ through R₄ are each individually and independently alkyl of from 1 to 24 carbon atoms, aryl, or substituted aryl of from 5 to 30 carbon atoms, heterocycle containing at least one nitrogen atom, or at least one oxygen atom, or at least one sulfur atom, or at least one boron atom, or at least one phosphorus atom, or at least one silicon atom, or any combination thereof, and substituents R₅ through R₂₀ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₅ through R₂₀ substituents form an annelated benzo-, naphtho-, anthra-, phenanthro-, fluorantheno-, pyreno-, triphenyleno-, or peryleno-substituent or its alkyl or aryl substituted derivative; or any two R₅ through R₂₀ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative. Other preferred analogous materials include a different central arene group, such as biphenyl or naphthalene, in place of the central benzene ring in the structure above. Other preferred analogous materials include a different central arene group, such as biphenyl or naphthalene, in place of the central benzene ring in the structure above. Yet other preferred analogous materials lack one of the two ethylene bridges in the structure above.

These materials possess fluorescence efficiencies as high as unity in solutions. Representative materials of this class include:
4-(Diphenylamino)-4′-[4-(diphenylamino)styryl]stilbene;
4-(Di-p-Tolylamino)-4′-[(di-p-tolylamino)styryl]stilbene (Blue-Green 2);
4,4′-[(2,5-Dimethoxy-1,4-phenylene)di-2,1-ethenediyl]bis[N,N-bis(4-methylphenyl)benzenamine;
4,4′-(1,4-Naphthalenediyldi-2,1-ethenediyl)bis[N,N-bis(4-methylphenyl)-benzenamine;
3,3′-(1,4-Phenylenedi-2,1-ethenediyl)bis[9-(4-ethylphenyl)-9H-carbazole;
4,4′-(1,4-Phenylenedi-2,1-ethenediyl)bis[N,N-diphenyl-1-naph-thalenamine;
4,4′-[1,4-Phenylenebis(2-phenyl-2,1-ethenediyl)]bis[N,N-diphenyl-benzenamine];
4,4′,4″-(1,2,4-Benzenetriyltri-2,1-ethenediyl)tris[N,N-diphenyl-benzenamine];
9,10-Bis[4-(di-p-tolylamino)styryl]anthracene; or
α,α′-(1,4-Phenylenedimethylidyne)bis[4-(diphenylamino)-1-naph-thaleneacetonitrile.

For green-emitting OLEDs, a class of fluorescent materials useful as the dopants in the present invention includes coumarin compounds: 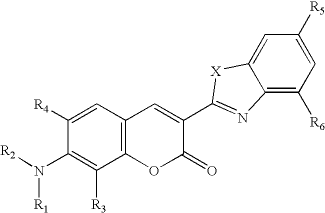
wherein:
X=S, O, or NR₇;
R₁ and R₂ are individually alkyl of from 1 to 20 carbon atoms, aryl or carbocyclic systems;
R₃ and R₄ are individually alkyl of from 1 to 10 carbon atoms, or a branched or unbranched 5 or 6 member substituent ring connecting with R₁ and R₂, respectively;
R₅ and R₆ are individually alkyl of from 1 to 20 carbon atoms, which are branched or unbranched; and
R₇ is any alkyl or aryl group.

These materials possess fluorescence efficiencies as high as unity in solutions. Representative materials of this class and their abbreviated names include:

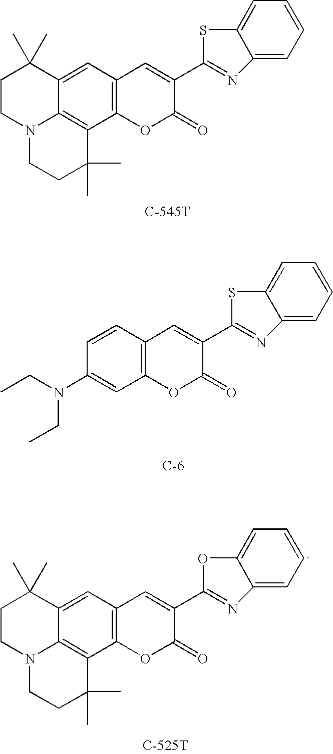

For green-emitting OLEDs, another class of fluorescent materials useful as the dopants in the present invention includes quinacridone compounds: 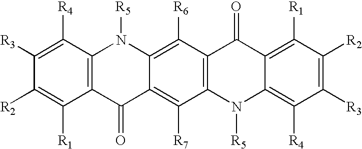
wherein:
substituents R₁ through R₇ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₄ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₄ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative.

These materials possess fluorescence efficiencies as high as unity in solutions. Representative materials of this class and their abbreviated names include:

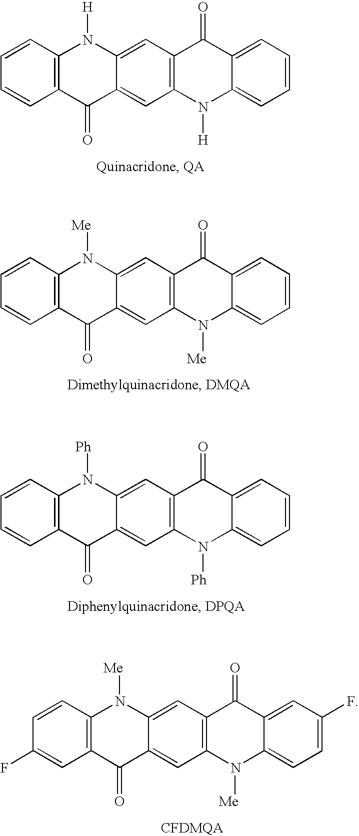

For green, green-yellow, and yellow emitting OLEDs, another class of fluorescent materials useful as the dopants in the present invention includes dipyridinomethene borate (DPMB) compounds: 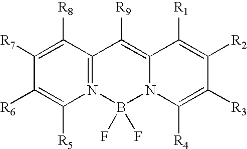
wherein:
substituents R₁ through R₉ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₉ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₉ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative.

These materials possess fluorescence efficiencies as high as unity in solutions. Representative materials of this class include:

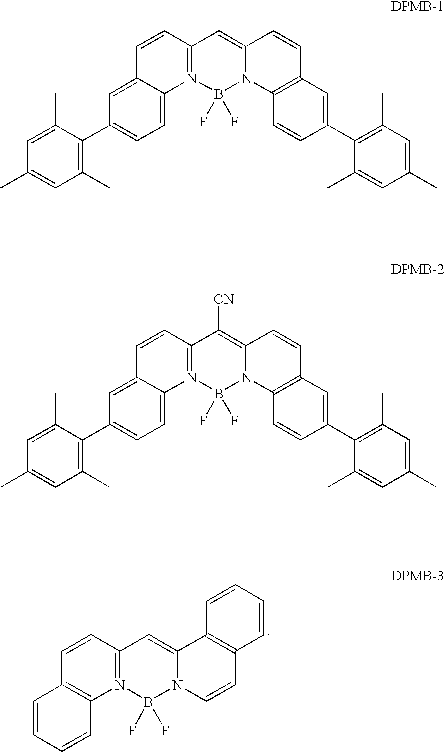

For yellow- and orange-emitting OLEDs, a preferred class of dopants for this invention includes indenoperylene compounds: 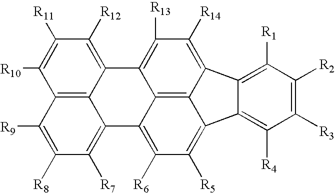
wherein:
substituents R₁ through R₁₄ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₄ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₄ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative.

These materials possess fluorescence efficiencies as high as unity in solutions. One representative material of this class is:

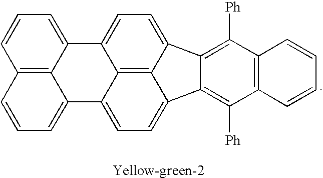

For yellow- and orange-emitting OLEDs, another preferred class of dopants for this invention includes naphthacene compounds: 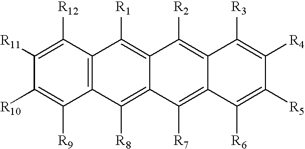
wherein:
substituents R₁ through R₁₂ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₂ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₂ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative.

These materials possess fluorescence efficiencies as high as unity in solutions and emit in the spectral region from greenish-yellow to red. Representative materials of this class and their abbreviated names include:
5,6,11,12-Tetraphenylnaphthacene (rubrene);
2,2′-[(6,11-Diphenyl-5,12-naphthacenediyl)di-4,1-phenylene]bis(6-methylbenzothiazole) (Orange 2);
5,12-Bis(2-mesityl)-6,11-diphenyltetracene;
5,6,11,12-Tetrakis(2-naphthyl)tetracene;
10,10′-[(6,11-Diphenyl-5,12-naphthacenediyl)di-4,1-phenylene]bis-[2,3,6,7-tetrahydro-1H,5H-benzothiazolo[5,6,7-ij]quinolizine;
5,6,13,14-Tetraphenylpentacene;
4,4′-(8,9-Dimethoxy-5,6,7,10,11,12-hexaphenyl-1,4-naphthacenediyl)bis-[N,N-diphenylbenzenamine];
6,11-Diphenyl-5,12-bis(4′-N,N-diphenylaminophenyl)naphthacene;
7,8,15,16-Tetraphenyl-benzo[a]pentacene; or
6,11-Diphenyl-5,12-bis(4′-cyanophenyl)naphthacene.

For red-emitting OLEDs, a preferred class of dopants of this invention is the DCM class, i.e. DCM compounds, and has the general formula: 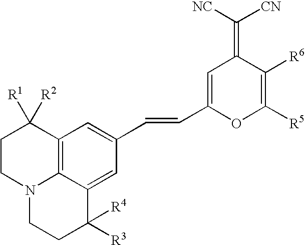
wherein:
R¹, R², R³, and R⁴ are individually alkyl of from 1 to 10 carbon atoms;
R⁵ is alkyl of from 2 to 20 carbon atoms, aryl, sterically hindered aryl, or heteroaryl; and
R⁶ is alkyl of from 1 to 10 carbon atoms, or a 5- or 6-membered carbocyclic, aromatic, or heterocyclic ring connecting with R⁵.

These materials possess fluorescence efficiencies as high as unity in solutions and emit in the orange and red spectral region. Representative materials of this class and their abbreviated names include:

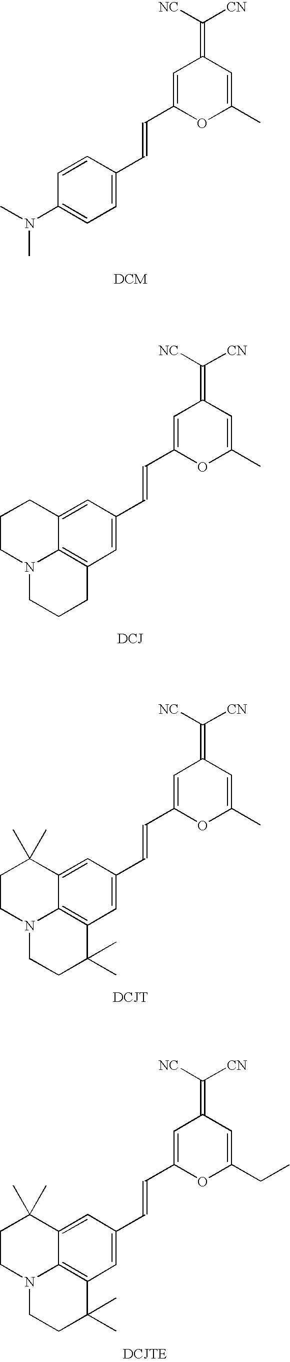

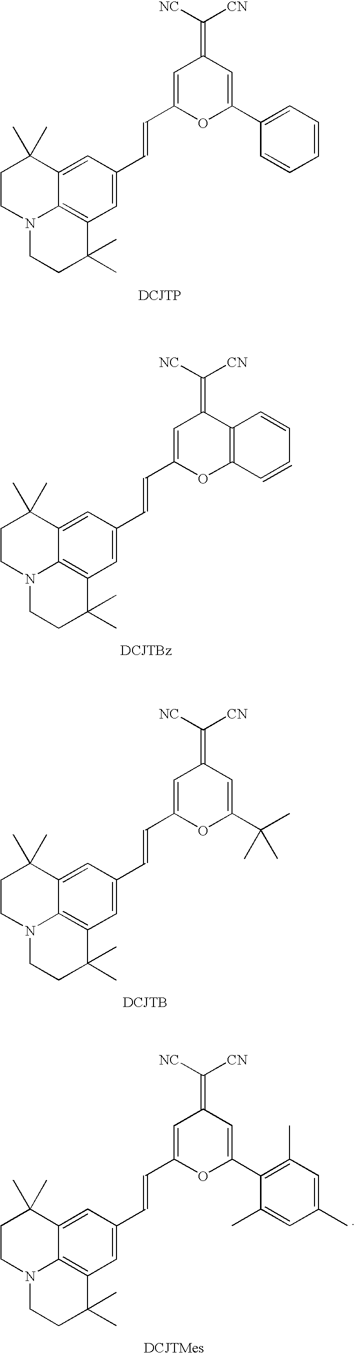

For red-emitting OLEDs, another preferred class of dopants of this invention includes periflanthene compounds: 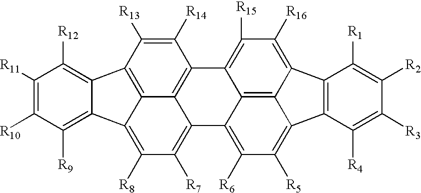
wherein:
substituents R₁ through R₁₆ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₆ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₆ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, or ace, or indeno substituent or their alkyl or aryl substituted derivative.

These materials possess fluorescence efficiencies as high as unity in solutions and emit in the orange and red spectral region. One representative material of this class is:

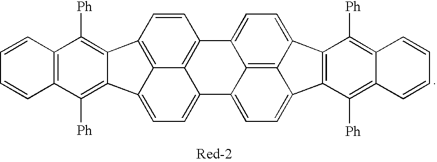

The composition of the light-emitting layer of this invention is such that the hole-trapping material can be present at 0.01 to less than 50% by volume relative to the light-emitting layer volume. The preferred range for the hole-trapping material is from 0.1 to 15% by volume relative to the light-emitting layer volume. The most preferred range is from 0.5 to less than 5% by volume relative to the light-emitting layer volume. The hole-trapping ability is often maximized around 1 to 4% by volume. The concentration range for a fluorescent dopant is from 0.1% to 10% by volume. The preferred concentration range for a fluorescent dopant is from 0.5% to 5% by volume. The concentration range for a phosphorescent dopant is from 0.1% to 20% by volume. The preferred concentration range for a phosphorescent dopant is from 1% to 10% by volume. The thickness of the light-emitting layer useful in this invention is between 50 Å and 5,000 Å. A thickness in this range is sufficiently large to enable recombination of charge carriers and, therefore, electroluminescence to take place exclusively in this layer. A preferred range is between 100 Å and 1,000 Å, where the overall OLED device performance parameters, including drive voltage, are optimal.

Electron-Transport Layer(s)

To achieve the objects of the present invention, certain electron-transport layer (ETL) materials and structures are required in addition to the described above LEL and HTL specifications. Thus, the ETL, disposed between the light-emitting layer(s) and the metallic cathode, includes an electron-transport material, which lowers or eliminates the barrier for electron injection from the cathode into the ETL and enhances electron transport across the layer. Examples of common cathode materials are: Mg:Ag alloy, LiF|Al, LiF|Ag, Li|Al, Li|Ag (where LiF or Li constitute a thin 1-10 Å electron-injection layer and Al or Ag constitute the cathode), Mg, Ca, and Ba.

The barrier reduction and the transport enhancement are determined with respect to the commonly employed ETL made of pure AlQ on top of which a common cathode of either Mg:Ag (20:1) alloy or LiF|Al is disposed. The barrier reduction and the transport enhancement are determined by testing a simple light-emitting device, wherein:
i″) the voltage drop across the ETL in the direction of the layer thickness is less than 0.007 V/Å at a drive current of 20 mA/cm² with Mg:Ag (20:1) cathode or less than 0.006 V/Å at a drive current of 20 mA/cm² with LiF|Al, Li|Al, LiF|Ag, or Li|Ag cathode; and
ii″) the electron-transport material enhances or at least does not significantly reduce (no more than 10-15%) the electroluminescent efficiency of the test device.

The test device has a simple structure: 1.1 mm glass | 250 Å ITO | 10 Å CFₓ|750 Å NPB | 375 Å AlQ Å 375 Å test ETL material | 2,100 Å Mg:Ag (20:1) or alternatively, in place of Mg:Ag alloy the cathode may be composed of a 5 A LiF electron-injection layer and 1,000 Å A1. Also, in place of CFₓ one may use other materials to modify the anode surface, as described above: CuPc, DPQHC, F₄TCNQ, molybdenum oxide, FeCl₃, FeF₃, etc. Thus, the test material is compared to pure AlQ as the ETL material using this simple device structure. The prepared test devices must be stored and the testing must be conducted at room temperature.

To properly measure the voltage drop across the ETL in V/Å, a simple series of test devices needs to be produced where the only variable is the thickness of the ETL. The ETL thickness can be varied, for example, from 100 Å to 1,000 Å with several points in between. The plot of the drive voltage for these devices, e.g., at 20 mA/cm², vs. the ETL thickness, usually can be satisfactorily fitted with a straight line and the tangent of the angle formed by the fitted straight line and the x axis is the voltage drop across the ETL in V/Å. Making such a graph for neat AlQ as the ETL material results in the voltage drop across the ETL of 0.007 V/Å at a drive current of 20 mA/cm² with Mg:Ag (20:1) cathode and 0.006 V/Å at a drive current of 20 mA/cm² with LiF|Al, Li|Al, LiF|Ag, or Li|Ag cathode.

If one assumes that the relationship between the drive voltage and the ETL thickness is linear, then a qualitative answer may be obtained, to a first approximation, by comparing the drive voltages of two test devices—one having AlQ as the ETL material (reference device) and the other having the test ETL material. If the drive voltage for the latter is significantly (e.g. at least by 10%) lower than that for the former then it is likely that the test ETL material will satisfy the V/Å requirement of this invention.

In one preferred embodiment of the present invention, the electron-transport layer includes at least one alkali metal or alkaline earth metal. Alkali metals are metals of Group 1A on the periodic table. Alkaline earth metals are metals in Group 2A on the periodic table. In one preferred embodiment the alkali metal is Li. In another preferred embodiment, the alkali metal is Cs.

Suitably the alkali metal or alkaline earth metal is dispersed in the electron-transport layer at a level of 0.01 to 40 volume %, and more preferably at a level of 0.1 to 35 volume %, and desirably at a level of 1.0 to 30 volume %. Depending on the alkali metal or alkaline earth metal chosen, the volume percentages that are desirable are those that correspond to a molar ratio of alkali metal or alkaline earth metal to electron-transport material in the electron-transport layer between 0.1:1 and 4:1. Often, the most desirable molar ratios are between 0.5:1 and 2:1.

In one desirable embodiment the electron-transport layer is further divided into at least two sublayers. In this case the sublayers can include the same electron-transport material or different electron-transport materials. At least one sublayer includes an alkali metal or alkaline earth metal. In one preferred embodiment, the alkali metal is Li. In another preferred embodiment, the alkali metal is Cs. Preferably, the sublayer including the alkali metal or alkaline earth metal is adjacent to the cathode. Preferably, the material of the sublayer adjacent to the light-emitting layer:

i) has a Lowest Unoccupied Molecular Orbital (LUMO) level equal to or lower (farther from the vacuum level) than that of the host of the light-emitting layer;

ii) has a Highest Occupied Molecular Orbital (HOMO) level lower (farther from the vacuum level) than those of the hole-trapping material and the host of the light-emitting layer; and

iii) does not include an alkali metal or alkaline earth metal.

Desirably the electron-transport layer includes an oxinoid compound as defined above for the host, except that there is no requirement for the peak emission wavelength of the material constituting the electron-transport layer to be at 475 nm or shorter. The illustrative of the useful oxinoid compounds are: tris(8-quinolinol)aluminum (AlQ₃ or simply AlQ), bis(8-quinolinol)magnesium (MgQ₂), tris(8-quinolinol)gallium (GaQ₃), 8-quinolinol lithium (LiQ), InQ₃, ScQ₃, ZnQ₂, BeBq₂ (bis(10-hydroxybenzo-[h]quinolinato)beryllium), Al(4-MeQ)₃, Al(2-MeQ)₃, Al(2,4-Me₂Q)₃, Ga(4-MeQ)₃, Ga(2-MeQ)₃, Ga(2,4-Me₂Q)₃, and Mg(2-MeQ)₂. The list of oxinoid compounds further includes metal complexes with two bi-dentate ligands and one mono-dentate ligand, for example Al(2-MeQ)₂(X) where X is any aryloxy, alkoxy, arylcaboxylate, and heterocyclic carboxylate group. In one desirable embodiment the electron-transport material includes AlQ₃.

Other electron-transport materials suitable for use in the electron-transport layer include various butadiene derivatives as disclosed in U.S. Pat. No. 4,356,429, various phenanthroline compounds as disclosed in EP 564,224 and EP 1 341 403 A1 and various heterocyclic optical brighteners as described in U.S. Pat. No. 4,539,507. Particularly useful phenanthroline compounds are BPhen, BCP, PA-2 as described in JP 2003 115387 A2 and JP 2004 311184 A2, and PA-3 as described in JP 2001 267080 A2 and WO 2002 043449 A1, which may or may not be doped with Li or Cs metal:

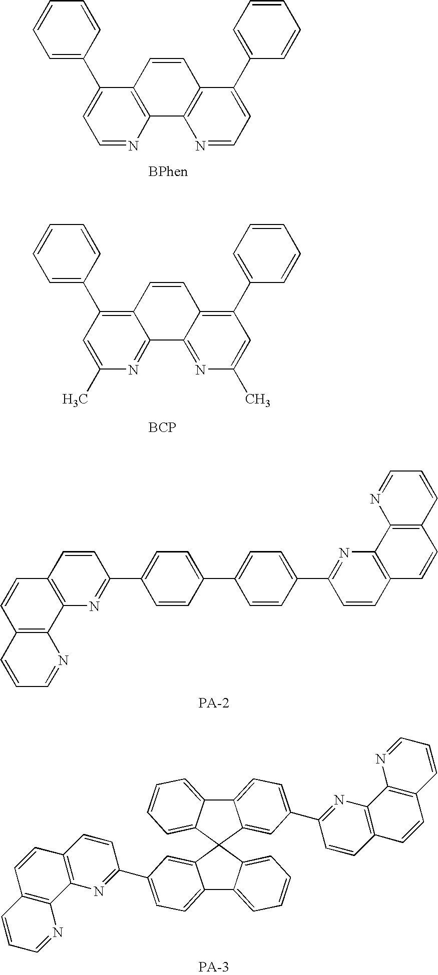

Benzazoles and triazines, for example see U.S. Pat. No. 6,225,467, are also useful electron transport materials. One example of benzazoles is TPBI. One example of a particularly useful triazine is Triazine 1:

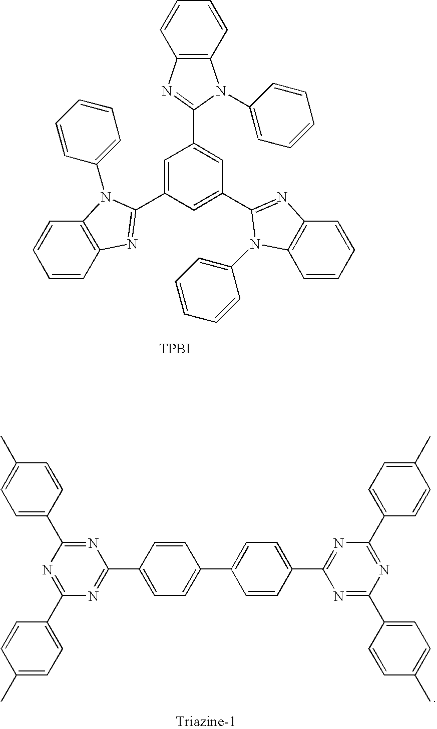

Another useful class of electron-transport materials includes various pyridine compounds as described in EP 1486 551 A1 and JP 2004 200162 A2, such as Pyr-3, which may or may not be doped with Li or Cs metal:

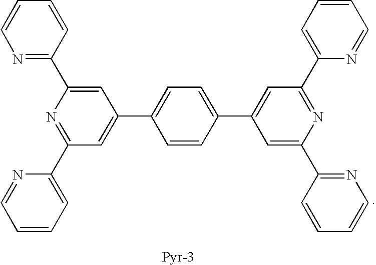

Another class of useful electron-transport materials includes various arene compounds having at least four fused benzene rings and their derivatives, as well as their mixtures with oxinoid compounds, phenanthroline compounds, or pyridine compounds, as described in Begley et. al. Docket 89132, 89133, and 89655. The neat arene compounds or their mixtures with other ETL materials may or may not be doped with Li or Cs metal.

According to the present invention, new materials and new compositions that improve electron injection and electron transport in a test OLED device while not adversely affecting its EL efficiency (at worst, 10-1 5% reduction may be tolerable) will result in improved EL efficiency in OLED devices containing a light-emitting layer(s) and a hole-transport layer(s) constructed according to the above specification.

When constructing test devices, it is preferable to use a Mg:Ag cathode. If the alternative cathode of LiF|Al is chosen, one should be aware that the trends using LiF|Al cathode are not always quantitatively similar to those observed with the Mg:Ag cathode. This is because, as known in the art, Li metal is generated from LiF upon reaction with a cathode material such as Al. It is also known in the art that Li metal diffuses through a layer of some compounds, such as BPhen, BCP, and other phenanthroline compounds efficiently at room temperature, while diffusion of Li metal in AlQ is by far smaller. Hence, Li metal generated from LiF may spread throughout the entire thickness of the ETL, if the latter is composed of a phenanthroline compound, which essentially would be similar to the situation where the entire ETL is doped with Li metal. This in turn would lead to lower voltage drop across such ETL. The magnitude of reduction is subject to the ETL thickness, the amount of Li generated, and time and temperature of device storage and may lead to non-linear drive voltage—ETL thickness dependencies.

Let us consider a comparison at a single ETL thickness. The voltage drop across the ETL for the 375 Å BPhen | 5 A LiF| 1,000 Å Al configuration is usually lower by ˜2 V at 20 mA/cm², than for the 375 Å BPhen 2,100 Å Mg:Ag configuration. Therefore, the same material, such as BPhen, may appear a better choice when tested with the LiF|Al cathode than when tested with Mg:Ag cathode. For reference, the voltage drop across the AlQ ETL is usually only ˜0.5 V lower for the 375 Å AlQ |5 Å LiF | 1,000 Å Al configuration than for the 375 Å AlQ | 2,100 Å Mg:Ag configuration.

Cathode

When light emission is through the anode, the cathode used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or a metal alloy. One preferred cathode material is comprised of a Mg:Ag alloy wherein the percentage of silver is in the range of I to 20%, as described in U.S. Pat. No. 4,885,221. Another suitable class of cathode materials includes bilayers comprised of a thin 1-10 Å electron-injection layer made of a low work function metal or metal salt capped with a thicker layer of conductive metal, e.g., LiF|Al (as described in U.S. Pat. No. 5,677,572), LiF|Ag, Li|AI, Li|Ag, CsF|Al, CsF|Ag, Cs|Al, and Cs|Ag. Another suitable class of cathode materials includes alkaline earth metals, such as Mg, Sr, Ca, and Ba. Other useful cathode materials include, but are not limited to, those disclosed in U.S. Pat. Nos. 5,059,861; 5,059,862; and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, and EP 1 076 368. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Deposition of Organic Layers A useful method for forming the light-emitting layer of the present invention is by vapor deposition in a vacuum chamber. This method is particularly useful for fabricating OLED devices, where the layer structure, including the organic layers, can be sequentially deposited on a substrate without significant interference among the layers. The material can be vaporized from an evaporation “boat” often comprised of a tantalum material, e.g., as described in U.S. Pat. No. 6,237,529, or can be first coated onto a donor sheet and then sublimed in closer proximity to the substrate. Layers with a mixture of materials can utilize separate evaporation boats or the materials can be pre-mixed and coated from a single boat or donor sheet. The thickness of each individual layer and its composition can be precisely controlled in the deposition process. To produce the desired composition of the light-emitting layer, the rate of deposition for each component is independently controlled using a deposition rate monitor.

Another useful method for forming the light-emitting layer of the present invention is by spin-coating or by ink-jet printing, where the material is deposited from a solvent, for example, with an optional binder to improve film formation. This method is particularly useful for fabricating lower-cost OLED devices. Composition of the light-emitting layer is determined by the concentration of each component in the solutions being coated. If the material is a polymer, solvent deposition is useful but other methods can be used, such as sputtering or thermal transfer from a donor sheet.

Patterned deposition can be achieved using shadow masks, integral shadow masks (U.S. Pat. No. 5,294,870), spatially-defined thermal dye transfer from a donor sheet (U.S. Pat. Nos. 5,688,551; 5,851,709; and 6,066,357) and inkjet method (U.S. Pat. No. 6,066,357).

Encapsulation

Most OLED devices are sensitive to moisture and/or oxygen so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890.

In addition, barrier layers such as SiOₓ, Teflon, and alternating inorganic/polymeric layers are known in the art for encapsulation. Any of these methods of sealing or encapsulation and desiccation can be used with the EL devices constructed according to the present invention.

Other

OLED devices of this invention can employ various well known optical effects in order to enhance their emissive properties if desired. This includes optimizing layer thicknesses to yield maximum light transmission, providing dielectric mirror structures, replacing reflective electrodes with light-absorbing electrodes, providing anti-glare or antireflection coatings over the display, providing a polarizing medium over the display, or providing colored, neutral density, or color-conversion filters over the display. Filters, polarizers, and anti-glare or antireflection coatings can be specifically provided over the EL device or as part of the EL device.

Embodiments of the invention can provide advantageous features such as higher EL efficiency, which approaches the theoretical maximum, low drive voltage, and high power efficiency. In accordance with the teachings of this invention, an organic light-emitting device satisfying all the specifications of this invention may emit not only blue or blue-green light but also other hues of colored light, such as green, yellow, orange, red, or white light (directly or through filters to provide multicolor displays) when appropriate LEL dopants are chosen. Embodiments of the invention can also provide an area lighting device. The invention and its advantages can be better appreciated by the following examples.

### EXAMPLES

### Examples T1-T8

### Test devices

OLED devices T1-T8 (Table 1) were prepared as follows. A glass substrate coated with ˜250 Å transparent indium-tin-oxide (ITO) conductive layer was cleaned and dried using a commercial glass scrubber tool. The ITO surface was subsequently treated with oxygen plasma to condition the surface as an anode. Over the ITO was deposited a ˜10 Å thick hole-injecting layer of fluorocarbon (CFₓ) by plasma-assisted deposition of CHF₃. The following layers were deposited in the following sequence by sublimation from heated crucible boats in a conventional vacuum deposition chamber under a vacuum of approximately 10⁻⁶ Torr (Table 1):
(1) the HTL, 750 Å thick, composed of NPB;
(2) the light-emitting layer, 375 Å thick, composed of AlQ;
(3) the ETL, 375 Å thick, composed of either AlQ (reference device Ti), AlQ doped with 3.7% Li, or a test ETL material, which is either undoped or doped with 3.7% Li;
(4) the cathode, 2,100 Å thick, including an alloy of magnesium and silver with a Mg:Ag volume ratio of 20:1.

Following that the devices were encapsulated in a nitrogen atmosphere along with calcium sulfate as a desiccant.

The EL characteristics of these devices were evaluated using a constant current source and a photometer. The drive voltage, EL efficiency in cd/A and W/A, and CIE coordinates at DC current densities ranging from relatively low, 0.5 mA/cm², to relatively high, 100 mA/cm², were measured and are reported at 20 mA/cm² in Table 1.

It should be noted that the drive voltage given in Table 1 is not corrected for the contact resistance and the ITO lead resistance which means that the voltage drop across the OLED device itself is lower by ˜1.5 V.

As can be seen from Table 1, the voltage drop across the improved ETL materials of devices T2-T8 is lower than that for the reference device TI having an ordinary ETL made of AlQ. As can be further seen from Table 1, the EL efficiencies for the devices T2-T8 are largely unaffected compared to the reference device TI. Thus, the ETL materials and compositions of devices T2-T8 satisfy the necessary requirements of this invention.

### Comparative and Inventive Examples 1-32

### Blue OLEDs

OLED devices 1-16 were prepared similarly to the test devices T1-T8, except for layers 1, 2, and 3, and used the same anode and the same cathode. The following layers were deposited in the following sequence (Table 2):
(1) where present, the first HTL composed of either 450 Å mTDATA or 550 Å mTDATA doped with 3% of F₄TCNQ;
(2) the second HTL, either 750, 300, or 200 Å thick, composed of NPB;
(3) the light-emitting layer, 400 Å thick, including

(i) TBADN as the host,

(ii) either 0.8% of Blue-2 or 1% of TBP as the dopant, and

(iii) where present, NPB as the hole-trapping material in certain % (indicated in Table 2; the range indicates that the performance of devices having NPB % in this range was found similar);
(4) where present, the first ETL, either 200 or 50 Å thick, composed of either AlQ or BPhen;
(5) where present, the second ETL, either 200 or 150 Å thick, composed of AlQ doped with 3.7% Li or BPhen doped with 3.7% Li or composed of C₆₀;

OLED devices 17-25 were prepared similarly to the devices 1-15, except in place of TBADN, AND was used as the LEL host.

OLED devices 26-32 were prepared similarly to the devices 1-15, except in place of TBADN, BPNA was used as the LEL host.

The EL characteristics of the devices 1-32 at 20 mA/cm² are reported in Table 2.

It should be noted that using a more reflective cathode of e.g. LiF|Al or LiF|Ag, would increase the EL efficiency by -5%. Further, the optical response function for the optical microcavity used in all of the devices in these examples is not at the maximum. To maximize the EL efficiency of blue light due to a better optical response, the distance between the emission zone and the LiF|Al cathode needs to be reduced to about 450 Å while the distance between the emission zone and the glass substrate needs to be increased to about 1,200 Å. This will increase the EL efficiency by another 5-10%. Furthermore, using ITO of better quality (less absorptive) could increase the EL efficiency by another 5-7%. At the same time, a 100-Å smaller LEL+ETL thickness, which is a part of the optimized geometry, and the better electron-injecting LiF|Al cathode would together result in ˜1.5 V lower drive voltage. The drive voltage given in Table 2 could also be corrected for the contact resistance and the ITO lead resistance which would further reduce the drive voltage by ˜1.5 V. Thus, the EL efficiency can be realistically improved further by 1.2 times overall while the drive voltage can be realistically lowered by ˜3 V overall.

As can be seen from Table 2, the EL efficiencies (cd/A, WIA, and photon/electron) for the simpler comparative devices 1-2, 7-9, 11, 17-18, 21, and 26-27, having only a host and a dopant in their LEL and various ETL compositions, are relatively low, 0.040-0.055 W/A.

As can be further seen from Table 2, the EL efficiencies for the comparative devices 3-5, 13, 19-20, 22, and 28-29, having a host, a hole-trapping material, and a dopant in their LEL and various ETL compositions, are relatively higher, 0.060-0.085 W/A.

As can be further seen from Table 2, the EL efficiencies for the inventive devices 14-16, 23-25, and 30-32, having a host, a hole-trapping material, and a dopant in their LEL, two HTL's as specified in the current invention, and various ETL compositions as specified in the current invention, are the highest, 0.084-0.127 W/A. With the best ETL compositions, the EL efficiencies are 0.100-0.127 W/A.

As can be seen from Table 2, the EL efficiency for the comparative device 6, having two HTL's as specified in the current invention but lacking the hole-trapping material in its LEL, though improved compared to the simpler comparative device 1, 0.051 W/A, remains far lower at 0.071 W/A compared to the EL efficiency of the inventive devices 14-16, 0.084-0.100 W/A. Furthermore, even if two HTL's are employed and a better ETL material and composition are used as in the comparative device 12 but the hole-trapping material is omitted from the LEL, the EL efficiency, though improved vs. that for device 7 at 0.047 W/A, still remains relatively low at 0.063 W/A, and actually equals that for the comparative device 13 having a simple HTL and ETL and a hole-trapping dopant in its LEL.

As can be seen from Table 2, the EL efficiencies for the comparative devices 2, 8, 18, and 27, having only a host and a dopant in their LEL and having an ETL made of AlQ+3.7% Li, which is known in the art to provide for better electron injection and electron transport compared to an ETL made of AlQ, are significantly lower, 0.037-0.039 W/A, compared to the EL efficiencies of the comparative devices 1, 7, 17, and 26, respectively, 0.047-0.057 W/A. This may be interpreted as due to some charge recombination events taking place in the vicinity of the ETL and thus undergoing quenching by the AlQ-Li radical-ion pair. If one introduces a hole-trapping material in an LEL of such a device having Li in the AlQ ETL, as in comparative devices 4-5, 20, and 29, which confines the charge recombination zone closer to the HTL|LEL interface, then the EL efficiency of such devices is either unchanged or actually improved to 0.077-0.086 W/A vs. that for the comparative devices 3, 19, and 28 at 0.070-0.078 W/A.

As can be seen from Table 2, the EL efficiency for the comparative device 10, having an ETL made of C₆₀, which is known in the art to provide for better electron injection and electron transport compared to an ETL made of AlQ, is nearly zero, because there is a large barrier for electron injection from C₆₀ into the LEL and the charge recombination zone is shifted to be in close proximity of the ETL and thus, C₆₀ quenches the EL. Even with a buffer layer of 50 Å of AlQ (i.e., the first ETL inserted between the LEL and the second ETL of C₆₀) the EL efficiency is still significantly reduced to 0.037 W/A compared to that of the comparative device 7 at 0.047 W/A, because there is still a large barrier for electron injection from the second ETL of C₆₀ into the first ETL of AlQ. An ETL made of other materials that act similarly, e.g., C₇₀ and other fullerenes and their mixtures, CuPc and other porphyrin and phthalocyanine derivatives, pentacene and pentacene derivatives, etc., would also lead to either nearly complete shutdown or significant reduction in EL efficiency.

### Comparative and Inventive Examples 33-43

### Blue-green OLEDs

OLED devices 33-43 were prepared similarly to the devices 1-15, except:
(i) in place of Blue-2 or TBP, Blue-green-2 was used as the dopant;
(ii) either TBADN, BPNA, 2,2′(DPA)₂, or ADN were used as the LEL host; and
(iii) only AlQ or AlQ+3.7% Li were used as ETL materials.

As can be seen from Table 2, the EL efficiencies (cd/A and W/A) for the simpler comparative devices 33-37, having an ordinary ETL, are relatively low, 0.095-0.105 W/A.

As can be further seen from Table 2, the EL efficiency for the comparative device 38, having an improved ETL composition, is higher, 0.120 W/A. Addition of a hole-trapping material to the LEL, as in device 39, leads to a further increase to 0.134 W/A.

As can be further seen from Table 2, the EL efficiencies for the inventive devices 40 and 41, having a host, a hole-trapping material, and a dopant in their LEL's, two HTL's as specified in the current invention, and either an ordinary ETL or an improved ETL composition as specified in the current invention, are the highest, 0.160-0.165 W/A. The reason that introduction of the improved ETL composition does not increase the EL efficiency may be that the efficiency is already at what is theoretically possible to achieve with a singlet emitter (only 25% of the produced excited states are emissive) and the light outcoupling efficiency (fraction of light leaving the device) of 20%.

As can be seen from Table 2, the EL efficiency of the Blue-green-2 dopant in some blue hosts known in the art, such as 2,2′(DPA)₂ and ADN, as in comparative devices 42 and 43, respectively, is significantly lower, around 0.060 W/A, vs. 0.100 W/A for the more suitable LEL hosts, such as TBADN and BPNA.

### Comparative Examples 44-56

### Green and Red Co-Host OLEDs

OLED devices 44-56 were prepared similarly to devices 1-15. The following layers were deposited in the following sequence (Table 3):
(1) where present, the first HTL, 450 Å thick, made of mTDATA;
(2) the second HTL, either 750 or 300 Å thick, made of NPB;
(3) the light-emitting layer, either 550 Å thick for green devices, or 600 or 700 Å thick for red devices, including

(i) either a mixture of AlQ and either NPB or DBP as the LEL host for green devices, or a mixture of AlQ and either DBP or rubrene as the LEL host for red devices; and

(ii) either 1.5% C545T as the dopant for green devices or 1% DCJTB or 0.3% Red-2 as the dopant for red devices;
(4) where present, the first ETL, either 350, 100 or 50 Å thick, made of AlQ;
(5) where present, the second ETL, 350, 300 or 250 Å thick, made of AlQ doped with 3.7% Li;
(6) the 2,100 Å cathode, including an alloy of magnesium and silver with a Mg:Ag volume ratio of 20:1.

As can be seen from Table 3, the EL efficiency (cd/A and W/A) remains the same or increases only slightly for green devices 45 and 46 having a mixed host of AlQ and NPB which is doped with C545T, two HTL's as specified in the current invention, and either an ordinary ETL or an improved ETL composition, i.e., 0.074-0.080 W/A, vs. 0.074 W/A for the reference device 44, having a simple HTL and a simple ETL.

As can be seen from Table 3, the EL efficiency increases only slightly for green devices 48 and 49 having a mixed host of AlQ and DBP which is doped with C545T, two HTL's as specified in the current invention, and either an ordinary ETL or an improved ETL composition, i.e., 0.069-0.072 W/A, vs. 0.063 W/A for the reference device 47, having a simple HTL and a simple ETL.

As can be seen from Table 3, the EL efficiency increases only slightly for red devices 51 and 52 having a mixed host of AlQ and DBP which is doped with DCJTB, two HTL's as specified in the current invention, and either an ordinary ETL or an improved ETL composition, i.e., 0.071-0.077 W/A, vs. 0.066 W/A for the reference device 50, having a simple HTL and a simple ETL.

As can be seen from Table 3, the EL efficiency does not change for red device 54 having a mixed host of AlQ and rubrene which is doped with Red-2, two HTL's as specified in the current invention, and an ordinary ETL, i.e., 0.080 W/A, vs. 0.080 W/A for the reference device 53, having a simple HTL and a simple ETL.

As can be seen from Table 3, the EL efficiency does not change for red device 56 having a mixed host of AlQ and rubrene which is doped with Red-2, two HTL's as specified in the current invention, and an improved ETL composition, i.e., 0.094 W/A, vs. 0.095 W/A for the reference device 55, having a simple HTL and a simple ETL.

Thus, one may conclude that defining the location of the charge recombination zone within the LEL, which is rendered by the hole-trapping material, is an important attribute of the current invention. Therefore, devices where the electrical charges can flow freely from one end of the LEL to the other, in particular holes in the direction of the ETL, in response to changes in the electric field strength inside the LEL and at the HTL|LEL and LEL|ETL interfaces, undergo strong changes in the location of the charge recombination zone and do not show large efficiency increases upon modification of the HTL and/or the ETL as described above. The presence of the two HTL's as specified above is another important factor in efficiency increase. Finally, improved ETL materials and compositions are a third significant factor and provide yet further improvement in the EL efficiency for the inventive devices.

The invention has been described in detail with particular reference to certain preferred embodiments thereof, but it will be understood that variations and modifications can be effected within the spirit and scope of the invention.

TABLE 1
Device data at 20 mA/cm²: test devices defining improved ETL materials
(device structure: glass 1.1 mm|250 Å ITO|10 Å CFₓ|750 Å NPB|375 Å AlQ|
375 Å test ETL material|2,100 Å Mg:Ag (20:1)

| | HTL - | LEL - | ETL - | | | | | |
|---|---|---|---|---|---|---|---|---|
| | material and | materials and | material and | | V/Å in | Efficiency, | Efficiency, | CIEₓ |
| Device | thickness, Å | thickness, Å | thickness, Å | Voltage, V | ETL | cd/A | W/A | CIE_{y} |
| T1 | NPB, 750 | AlQ, 375 | AlQ, 375 | 8.0 | 0.0070 | 3.0 | 0.021 | 0.340 |
| | | | | | | | | 0.550 |
| T2 | NPB, 750 | AlQ, 375 | Triazine-1, 375 | 7.2 | 0.0049 | 3.1 | 0.022 | 0.356 |
| | | | | | | | | 0.544 |
| T3 | NPB, 750 | AlQ, 375 | AlQ + 3.7% Li, 375 | 7.0 | 0.0043 | 3.0 | 0.022 | 0.341 |
| | | | | | | | | 0.552 |
| T4 | NPB, 750 | AlQ, 375 | GaQ + 3.7% Li, 375 | 6.5 | 0.0030 | 2.9 | 0.020 | 0.343 |
| | | | | | | | | 0.549 |
| T5 | NPB, 750 | AlQ, 375 | BPhen, 375 | 7.5 | 0.0057 | 3.1 | 0.023 | 0.335 |
| | | | | | | | | 0.550 |
| T6 | NPB, 750 | AlQ, 375 | BPhen + 3.7% Li, 375 | 5.7 | 0.0009 | 3.0 | 0.021 | 0.334 |
| | | | | | | | | 0.552 |
| T7 | NPB, 750 | AlQ, 375 | Pyr-3 + 3.7% Li, 375 | 5.4 | 0.0001 | 3.1 | 0.023 | 0.325 |
| | | | | | | | | 0.547 |
| T8 | NPB, 750 | AlQ, 375 | TPBI + 3.7% Li, 375 | 5.7 | 0.0009 | 2.9 | 0.020 | 0.352 |
| | | | | | | | | 0.554 |

TABLE 2
Device data at 20 mA/cm²: comparison of comparative and inventive blue and blue-green OLEDs
(device structure: 1.1 mm glass|250 Å ITO|10 Å CFₓ|HTL1|HTL2|LEL|ETL1|ETL2|2,100 Å Mg:Ag, 20:1).
BLUE OLEDs

| | | | | | | | | | | |
|---|---|---|---|---|---|---|---|---|---|---|
| | | | HTL2 - | | ETL1 - | | | | | |
| | | | material | | material | | | | | |
| | | HTL1 - | and | | and | ETL2 - | Volt- | Effi- | Effi- | |
| | | material and | thickness, | LEL - | thickness, | material and | age, | ciency, | ciency, | CIEₓ |
| Device | Type | thickness, Å | Å | materials and thickness, Å | Å | thickness, Å | V | cd/A | W/A | CIE_{y} |

TBADN host

| | | | | | | | | | | |
|---|---|---|---|---|---|---|---|---|---|---|
| 1 | Comparative | none | NPB, 750 | TBADN + 0.8% Blue2, 400 | Alq, 200 | none | 8.2 | 2.1 | 0.051 | 0.141 |
| | | | | | | | | | | 0.129 |
| 2 | Comparative | none | NPB, 750 | TBADN + 0.8% Blue2, 400 | none | Alq + 3.7% Li, | 7.5 | 1.8 | 0.038 | 0.134 |
| | | | | | | 200 | | | | 0.144 |
| 3 | Comparative | none | NPB, 750 | TBADN + 0.8% Blue2 + from 2 | Alq, 200 | none | 8.0 | 3.0 | 0.078 | 0.142 |
| | | | | to 12% NPB, 400 | | | | | | 0.125 |
| 4 | Comparative | none | NPB, 750 | TBADN + 0.8% Blue2 + from 2 | none | Alq + 3.7% Li, | 7.7 | 3.7 | 0.077 | 0.143 |
| | | | | to 12% NPB, 400 | | 200 | | | | 0.144 |
| 5 | Comparative | none | NPB, 750 | TBADN + 0.8% Blue2 + from 2 | Alq, 50 | Alq + 3.7% Li, | 7.3 | 4.1 | 0.086 | 0.141 |
| | | | | to 12% NPB, 400 | | 150 | | | | 0.155 |
| 6 | Comparative | mTDATA, | NPB, 300 | TBADN + 0.8% Blue2, 400 | Alq, 200 | none | 11.4 | 3.7 | 0.071 | 0.162 |
| | | 450 | | | | | | | | 0.162 |
| 7 | Comparative | none | NPB, 750 | TBADN + 1% TBP, 400 | Alq, 200 | none | 7.9 | 2.6 | 0.047 | 0.138 |
| | | | | | | | | | | 0.190 |
| 8 | Comparative | none | NPB, 750 | TBADN + 1% TBP, 400 | none | Alq + 3.7% Li, | 7.3 | 2.2 | 0.038 | 0.134 |
| | | | | | | 200 | | | | 0.185 |
| 9 | Comparative | none | NPB, 750 | TBADN + 1% TBP, 400 | none | BPhen + 3.7% | 5.6 | 3.0 | 0.056 | 0.136 |
| | | | | | | Li, 200 | | | | 0.186 |
| 10 | Comparative | none | NPB, 750 | TBADN + 1% TBP, 400 | none | C₆₀, 200 | 7.2 | 0 | 0 | — |
| 11 | Comparative | none | NPB, 750 | TBADN + 1% TBP, 400 | Alq, 50 | C₆₀, 150 | 6.3 | 1.9 | 0.037 | 0.138 |
| | | | | | | | | | | 0.171 |
| 12 | Comparative | mTDATA + | NPB, 200 | TBADN + 1% TBP, 400 | BPhen, 50 | BPhen + 3.7% | 7.5 | 4.0 | 0.063 | 0.138 |
| | | 3% | | | | Li, 150 | | | | 0.245 |
| | | F₄TCNQ, | | | | | | | | |
| | | 550 | | | | | | | | |
| 13 | Comparative | none | NPB, 750 | TBADN + 1% TBP + from 2 to | Alq, 200 | none | 7.7 | 3.4 | 0.062 | 0.136 |
| | | | | 15% NPB, 400 | | | | | | 0.189 |
| 14 | Inventive | mTDATA, | NPB, 300 | TBADN + 0.8% Blue2 + 3.5% NPB, | Alq, 200 | none | 10.8 | 4.5 | 0.091 | 0.144 |
| | | 450 | | 400 | | | | | | 0.160 |
| 15 | Inventive | mTDATA, | NPB, 300 | TBADN + 0.8% Blue2 + 3.5% NPB, | none | Alq + 3.7% Li, | 10.6 | 4.0 | 0.084 | 0.145 |
| | | 450 | | 400 | | 200 | | | | 0.154 |
| 16 | Inventive | mTDATA, | NPB, 300 | TBADN + 0.8% Blue2 + 3.5% NPB, | Alq, 50 | Alq + 3.7% Li, | 10.0 | 4.7 | 0.100 | 0.145 |
| | | 450 | | 400 | | 150 | | | | 0.164 |

ADN host

| | | | | | | | | | | |
|---|---|---|---|---|---|---|---|---|---|---|
| 17 | Comparative | none | NPB, 750 | ADN + 0.8% Blue2, 400 | Alq, 200 | none | 8.6 | 2.5 | 0.055 | 0.144 |
| | | | | | | | | | | 0.141 |
| 18 | Comparative | none | NPB, 750 | ADN + 0.8% Blue2, 400 | none | Alq + 3.7% Li, | 7.7 | 1.9 | 0.039 | 0.138 |
| | | | | | | 200 | | | | 0.141 |
| 19 | Comparative | none | NPB, 750 | ADN + 0.8% Blue2 + from 1 to | Alq, 200 | none | 8.5 | 3.1 | 0.070 | 0.144 |
| | | | | 9% NPB, 400 | | | | | | 0.144 |
| 20 | Comparative | none | NPB, 750 | ADN + 0.8% Blue2 + from 1 to | none | Alq + 3.7% Li, | 7.5 | 3.7 | 0.085 | 0.142 |
| | | | | 9% NPB, 400 | | 200 | | | | 0.140 |
| 21 | Comparative | none | NPB, 750 | ADN + 1% TBP, 400 | Alq, 200 | none | 8.7 | 3.1 | 0.054 | 0.141 |
| | | | | | | | | | | 0.200 |
| 22 | Comparative | none | NPB, 750 | ADN + 1% TBP + from 1 to 9% | Alq, 200 | none | 8.5 | 4.6 | 0.078 | 0.137 |
| | | | | NPB, 400 | | | | | | 0.209 |
| 23 | Inventive | mTDATA, | NPB, 300 | ADN + 0.8% Blue2 + 2% NPB, | Alq, 200 | none | 11.9 | 5.0 | 0.105 | 0.147 |
| | | 450 | | 400 | | | | | | 0.150 |
| 24 | Inventive | mTDATA, | NPB, 300 | ADN + 0.8% Blue2 + 2% NPB, | none | Alq + 3.7% Li, | 10.5 | 5.1 | 0.105 | 0.149 |
| | | 450 | | 400 | | 200 | | | | 0.153 |
| 25 | Inventive | mTDATA, | NPB, 300 | ADN + 0.8% Blue2 + 2% NPB, | Alq, 50 | Alq + 3.7% Li, | 10.9 | 6.0 | 0.127 | 0.148 |
| | | 450 | | 400 | | 150 | | | | 0.150 |

BPNA host

| | | | | | | | | | | |
|---|---|---|---|---|---|---|---|---|---|---|
| 26 | Comparative | none | NPB, 750 | BPNA + 0.8% Blue2, 400 | Alq, 200 | none | 7.2 | 2.5 | 0.057 | 0.150 |
| | | | | | | | | | | 0.140 |
| 27 | Comparative | none | NPB, 750 | BPNA + 0.8% Blue2, 400 | none | Alq + 3.7% Li, | 6.8 | 1.8 | 0.037 | 0.136 |
| | | | | | | 200 | | | | 0.147 |
| 28 | Comparative | none | NPB, 750 | BPNA + 0.8% Blue2 + from 1 to | Alq, 200 | none | 7.6 | 3.2 | 0.070 | 0.144 |
| | | | | 7% NPB, 400 | | | | | | 0.144 |
| 29 | Comparative | none | NPB, 750 | BPNA + 0.8% Blue2 + from 1 to | none | Alq + 3.7% Li, | 6.8 | 3.5 | 0.082 | 0.145 |
| | | | | 7% NPB, 400 | | 200 | | | | 0.139 |
| 30 | Inventive | mTDATA, | NPB, 300 | BPNA + 0.8% | Alq, 200 | none | 11.5 | 5.5 | 0.105 | 0.156 |
| | | 450 | | Blue2 + 2.5% NPB, 400 | | | | | | 0.165 |
| 31 | Inventive | mTDATA, | NPB, 300 | BPNA + 0.8% | none | Alq + 3.7% Li, | 10.0 | 5.7 | 0.105 | 0.160 |
| | | 450 | | Blue2 + 2.5% NPB, 400 | | 200 | | | | 0.174 |
| 32 | Inventive | mTDATA, | NPB, 300 | BPNA + 0.8% | Alq, 50 | Alq + 3.7% Li, | 10.8 | 6.9 | 0.117 | 0.160 |
| | | 450 | | Blue2 + 2.5% NPB, 400 | | 150 | | | | 0.200 |

BLUE-GREEN OLEDs

| | | | | | | | | | | |
|---|---|---|---|---|---|---|---|---|---|---|
| 33 | Comparative | none | NPB, 750 | TBADN + 2.5% Blue-green2, | Alq, 350 | none | 7.4 | 7.5 | 0.094 | 0.155 |
| | | | | 200 | | | | | | 0.310 |
| 34 | Comparative | none | NPB, 750 | TBADN + 2.5% Blue-green2, | Alq, 200 | none | 8.0 | 8.8 | 0.105 | 0.159 |
| | | | | 400 | | | | | | 0.335 |
| 35 | Comparative | none | NPB, 750 | TBADN + 2.5% Blue-green2 + from | Alq, 350 | none | 7.2 | 8.3 | 0.104 | 0.164 |
| | | | | 2 to 10% NPB, 200 | | | | | | 0.307 |
| 36 | Comparative | none | NPB, 750 | BPNA + 3% Blue-green2, 200 | Alq, 400 | none | 7.4 | 8.9 | 0.099 | 0.168 |
| | | | | | | | | | | 0.376 |
| 37 | Comparative | none | NPB, 750 | BPNA + 3% Blue-green2, 400 | Alq, 200 | none | 8.5 | 10.4 | 0.105 | 0.174 |
| | | | | | | | | | | 0.427 |
| 38 | Comparative | none | NPB, 750 | BPNA + 3% Blue-green2, 400 | none | Alq + 3.7% Li, | 7.2 | 12.0 | 0.120 | 0.175 |
| | | | | | | 200 | | | | 0.430 |
| 39 | Comparative | none | NPB, 750 | BPNA + 3% Blue-green2 + from | none | Alq + 3.7% Li, | 7.9 | 12.4 | 0.134 | 0.164 |
| | | | | 2 to 7% NPB, 400 | | 200 | | | | 0.392 |
| 40 | Inventive | mTDATA, | NPB, 300 | BPNA + 3% Blue-green2 + 5% | Alq, 200 | none | 11.5 | 17.1 | 0.165 | 0.176 |
| | | 450 | | NPB, 400 | | | | | | 0.431 |
| 41 | Inventive | mTDATA, | NPB, 300 | BPNA + 3% Blue-green2 + 5% | Alq, 50 | Alq + 3.7% Li, | 10.0 | 16.6 | 0.160 | 0.177 |
| | | 450 | | NPB, 400 | | 150 | | | | 0.432 |
| 42 | Comparative | none | NPB, 750 | 2,2′(DPA)₂ + 3% Blue-green2, | Alq, 200 | none | 7.6 | 6.8 | 0.061 | 0.210 |
| | | | | 400 | | | | | | 0.470 |
| 43 | Comparative | none | NPB, 750 | ADN + 3% Blue-green2, 400 | Alq, 200 | none | 6.5 | 5.5 | 0.058 | 0.182 |
| | | | | | | | | | | 0.398 |

TABLE 3
Device data at 20 mA/cm²: negative examples of green and red OLEDs
(device structure: 1.1 mm glass|250 Å ITO|10 Å CFₓ|HTL1|HTL2|LEL|ETL1|ETL2|2,100 Å Mg:Ag, 20:1).

| | | | HTL2 - | | ETL1 - | | | | | |
|---|---|---|---|---|---|---|---|---|---|---|
| | | | material | | material | | | | | |
| | | HTL1 - | and | | and | ETL2 - | Volt- | Effi- | Effici- | |
| | | material and | thickness, | LEL - | thickness, | material and | age, | ciency, | ency, | CIEₓ |
| Device | Type | thickness, Å | Å | materials and thickness, Å | Å | thickness, Å | V | cd/A | W/A | CIE_{y} |
| 44 | Comparative | none | NPB, 750 | Alq + 1.5% C545T + 50% NPB, | Alq, 350 | none | 8.5 | 11.9 | 0.074 | 0.284 |
| | | | | 550 | | | | | | 0.656 |
| 45 | Comparative | mTDATA, | NPB, 300 | Alq + 1.5% C545T + 50% NPB, | Alq, 350 | none | 11.9 | 12.0 | 0.074 | 0.291 |
| | | 450 | | 550 | | | | | | 0.652 |
| 46 | Comparative | mTDATA, | NPB, 300 | Alq + 1.5% C545T + 50% NPB, | Alq, 50 | Alq + 3.7% Li, | 10.5 | 13.1 | 0.080 | 0.293 |
| | | 450 | | 550 | | 300 | | | | 0.652 |
| 47 | Comparative | none | NPB, 750 | Alq + 1.5% C545T + 33% DBP, | Alq, 350 | none | 8.4 | 10.4 | 0.063 | 0.324 |
| | | | | 550 | | | | | | 0.638 |
| 48 | Comparative | mTDATA, | NPB, 300 | Alq + 1.5% C545T + 33% DBP, | Alq, 350 | none | 11.3 | 11.4 | 0.069 | 0.327 |
| | | 450 | | 550 | | | | | | 0.634 |
| 49 | Comparative | mTDATA, | NPB, 300 | Alq + 1.5% C545T + 33% DBP, | none | Alq + 3.7% Li, | 9.3 | 11.9 | 0.072 | 0.328 |
| | | 450 | | 550 | | 350 | | | | 0.633 |
| 50 | Comparative | none | NPB, 750 | Alq + 1% DCJTB + 33% DBP, | Alq, 350 | none | 8.5 | 3.6 | 0.066 | 0.649 |
| | | | | 600 | | | | | | 0.348 |
| 51 | Comparative | mTDATA, | NPB, 300 | Alq + 1% DCJTB + 33% DBP, | Alq, 350 | none | 11.8 | 3.9 | 0.071 | 0.649 |
| | | 450 | | 600 | | | | | | 0.348 |
| 52 | Comparative | mTDATA, | NPB, 300 | Alq + 1% DCJTB + 33% DBP, | none | Alq + 3.7% Li, | 10.6 | 4.3 | 0.077 | 0.650 |
| | | 450 | | 600 | | 350 | | | | 0.348 |
| 53 | Comparative | none | NPB, 750 | Alq + 0.3% Red2 + 45% Rubrene, | Alq, 350 | none | 8.2 | 5.1 | 0.080 | 0.654 |
| | | | | 700 | | | | | | 0.342 |
| 54 | Comparative | mTDATA, | NPB, 300 | Alq + 0.3% Red2 + 45% Rubrene, | Alq, 350 | none | 12.0 | 5.0 | 0.080 | 0.655 |
| | | 450 | | 700 | | | | | | 0.342 |
| 55 | Comparative | none | NPB, 750 | Alq + 0.3% Red2 + 45% Rubrene, | Alq, 100 | Alq + 3.7% Li, | 7.6 | 6.0 | 0.095 | 0.658 |
| | | | | 700 | | 250 | | | | 0.340 |
| 56 | Comparative | mTDATA, | NPB, 300 | Alq + 0.3% Red2 + 45% Rubrene, | Alq, 100 | Alq + 3.7% Li, | 10.7 | 5.8 | 0.094 | 0.659 |
| | | 450 | | 700 | | 250 | | | | 0.339 |

### PARTS LIST

10 electrical conductors
100 OLED device
110 substrate
120 anode
130 EL medium
140 cathode
200 OLED device
210 substrate
220 anode
230 EL medium
231 hole-transport layer
232 light-emitting layer
233 electron-transport layer
240 cathode
300 OLED device
310 substrate
320 anode
330 EL medium
331 hole-injection layer or hole-transport layer 1
332 hole-transport layer or hole-transport layer 2
333 light-emitting layer
334 electron-transport layer or electron-transport layer 1
335 electron-injection layer or electron transport layer 2
340 cathode

1. An organic light-emitting device, comprising:
a) a substrate;
b) an anode and a cathode disposed over the substrate;
c) a first hole-transport layer provided over the anode and having at least a first material which is organic or inorganic, wherein the first material has an oxidation potential in the range of from 0 to +1.1 V vs. SCE;
d) a second hole-transport layer provided over the first hole-transport layer, and having at least a second material, which is organic, wherein
i) the second material has an oxidation potential that is in the range of from +0.4 to +1.4 V vs. SCE;
ii) the second material has an oxidation potential that is at least 0.2 V greater than the oxidation potential of the first material; and
iii) the second material has a peak emission wavelength at 475 nm or shorter;
e) at least one light-emitting layer disposed over the second hole-transport layer wherein the light-emitting layer(s) includes a host, a dopant, and a hole-trapping material, wherein
i) the hole-trapping material is provided to be 0.1 to less than 15% by volume relative to its corresponding light-emitting layer volume, and has an oxidation potential in a range of from +0.4 to +1.1 V vs. SCE, wherein the oxidation potential is selected so that it is less than the oxidation potential of its corresponding host by at least 0.1 V (or the HOMO level for the hole-trapping material is closer to the vacuum level by at least 0.1 eV compared to the HOMO level of its corresponding host) in order to serve as a hole trap, and wherein the oxidation potential is further selected so as to avoid formation of a harmful charge transfer complex between the hole-trapping material and the host, and to avoid formation of a harmful charge transfer complex between the hole-trapping material and the dopant;
ii) the host of the light-emitting layer being selected to include at least one organic electrical charge transport material, which has an oxidation potential of +1.0 V or higher vs. SCE , and has a peak emission wavelength at 475 nm or shorter, and which when mixed with the hole-trapping material forms a continuous and substantially pin-hole-free layer; and
iii) the dopant of the light-emitting layer being selected to produce colored light and to have the energy of the emissive electronic state that is smaller than the energy of the corresponding (lowest excited singlet or lowest triplet) electronic state of each of the following: the second material, the host, and the hole-trapping material; and
f) an electron-transport layer disposed between the light-emitting layer(s) and the cathode wherein the electron-transport layer includes an electron-transport material which lowers or eliminates the barrier for electron injection from the metallic cathode into the electron-transport layer and enhances electron transport across the layer, where the barrier reduction and the transport enhancement are determined by testing a simple light-emitting device, wherein
i) the voltage drop across the electron-transport layer in the direction of the layer thickness is less than 0.007 V/angstrom at a drive current of 20 mA/cm² with a Mg:Ag (20:1) cathode; and
ii) the electron-transport material enhances or at least does not significantly reduce the electroluminescent efficiency of the test device.

2. An organic light-emitting device, comprising:
a) a substrate;
b) an anode and a cathode disposed over the substrate;
c) a first hole-transport layer provided over the anode and having at least a first material which is an amine compound, wherein the first material has an oxidation potential in the range of from 0 to +1.1 V vs. SCE;
d) a second hole-transport layer provided over the first hole-transport layer, and having at least a second material, which is an amine compound, wherein
i) the second material has an oxidation potential that is in the range of from +0.4 to +1.4 V vs. SCE;
ii) the second material has an oxidation potential that is at least 0.2 V greater than the oxidation potential of the first material;
iii) the second material has a peak emission wavelength at 475 nm or shorter;
e) at least one light-emitting layer provided over the second hole-transport layer wherein the light-emitting layer(s) includes a host, a dopant, and a hole-trapping material, wherein
i) the hole-trapping material is an amine compound provided to be 0.1 to less than 15% by volume relative to its corresponding light-emitting layer volume, and the hole-trapping material has an oxidation potential in a range of from +0.4 to +1.1 V vs. SCE, wherein the oxidation potential is selected so that it is less than the oxidation potential of its corresponding host by at least 0.1 V (or the HOMO level for the hole-trapping material is closer to the vacuum level by at least 0.1 eV compared to the HOMO level of its corresponding host) in order to serve as a hole trap, and wherein the oxidation potential is further selected so as to avoid formation of a harmful charge transfer complex between the hole-trapping material and the host, and to avoid formation of a harmful charge transfer complex between the hole-trapping material and the dopant;
ii) the host of the light-emitting layer being selected to include at least one organic electrical charge transport material, which is an anthracene compound and which has an oxidation potential of +1.0 V or higher vs. SCE , and has a peak emission wavelength at 475 nm or shorter, and which when mixed with the hole-trapping material forms a continuous and substantially pin-hole-free layer; and
iii) the dopant of the light-emitting layer being selected to produce colored light and to have the energy of the emissive electronic state that is smaller than the energy of the corresponding (lowest excited singlet or lowest triplet) electronic state of each of the following: the second material, the host, and the hole-trapping material; and
f) an electron-transport layer disposed between the light-emitting layer(s) and the cathode wherein the electron-transport layer includes an electron-transport material which lowers or eliminates the barrier for electron injection from the metallic cathode into the electron-transport layer and enhances electron transport across the layer, where the barrier reduction and the transport enhancement are determined by testing a simple light-emitting device, wherein
i) the voltage drop across the electron-transport layer in the direction of the layer thickness is less than 0.007 V/angstrom at a drive current of 20 mA/cm² with Mg:Ag (20:1) cathode; and
ii) the electron-transport material enhances or at least does not reduce the electroluminescent efficiency of the test device.

3. The organic light-emitting device of claim 1 wherein the first material includes a porphyrin, phthalocyanine, phosphazine, para-phenylenediamine, dihydrophenazine, 2,6-diaminonaphthalene,2,6-diaminoanthracene, 2,6,9,10-tetraaminoanthracene, anilinoethylene, N,N,N,N-tetraarylbenzidine, mono- or polyaminated perylene, mono- or polyaminated coronene, polyaminated pyrene, mono- or polyaminated fluoranthene, mono- or polyaminated chrysene, mono- or polyaminated anthanthrene, mono- or polyaminated triphenylene, or mono- or polyaminated tetracene moiety and the second material includes an amine compound having a N,N,N,N-tetraarylbenzidine, diaminonaphthalene, aminopyrene, aminocoronene, or a N-arylcarbazole moiety.

4. The organic light-emitting device of claim 1 wherein the first material either contains a dopant which is a strong enough oxidizing agent to form an ion pair with the first material or a neat layer of such a strong oxidizing agent is disposed between the anode and the first hole-transport layer.

5. The organic light-emitting device of claim 1 wherein the organic light-emitting layer(s) emits blue or blue-green light, the hole-trapping material includes an amine compound, and the host includes either an anthracene compound or a carbazole compound.

6. The organic light-emitting device of claim 5 wherein the anthracene host includes
2-(1,1-dimethylethyl)-9,10-bis(2-naphthalenyl)anthracene (TBADN);
9,10-bis(2-naphthalenyl)anthracene (ADN);
9-biphenyl-10-(2-naphthalenyl)-anthracene (BPNA);
9,10-bis(1-naphthalenyl)anthracene;
9,10-Bis[4-(2,2-diphenylethenyl)phenyl]anthracene;
9,10-Bis([1,1′:3′,1″-terphenyl]-5′-yl)anthracene;
9,9′-Bianthracene;
10,10′-Diphenyl-9,9′-bianthracene;
10,10′-Bis([1,1′:3′,1″-terphenyl]-5′-yl)-9,9′-bianthracene;
2,2′-Bianthracene;
9,10-bis(6-cyano-2-naphthalenyl)anthracene (ADN(CN)₂);
9,9′,10,10′-Tetraphenyl-2,2′-bianthracene;
9,10-Bis(2-phenylethenyl)anthracene; or
9-Phenyl-10-(phenylethynyl)anthracene.

7. The organic light-emitting device of claim 1 wherein the host includes an oxinoid compound, a metal 2-hydroxypyridinyl complex, a heterocyclic benzenoid compound, an amine compound, a carbazole compound, a styryl compound, or a fluorene compound.

8. The organic light-emitting device of claim 1 wherein the color of emission is blue or blue-green and the oxidation potential for the hole-trapping material which is an amine compound is in a range of from +0.6 to +1.1 V, while the oxidation potential for the host which is an anthracene compound is +1.2 V or higher vs. SCE.

9. The organic light-emitting device of claim 1 wherein the color of emission is green or yellow and the oxidation potential for the hole-trapping material which is an amine compound is in a range of from +0.4 to +0.9 V, while the oxidation potential for the host is +1.0 V or higher vs. SCE.

10. The organic light-emitting device of claim 1 wherein the color of emission is orange or red and the oxidation potential for the hole-trapping material which is an amine compound is in a range of from +0.2 to +0.7 V, while the oxidation potential for the host is +0.8 V or higher vs. SCE.

11. The organic light-emitting device of claim 1 wherein the hole-trapping material includes N,N′-bis(1-naphthalenyl)-N,N′-diphenylbenzidine (NPB), N,N′-bis(1-naphthalenyl)-N,N′-bis(2-naphthalenyl)benzidine (TNB), N,N′-bis(3-methylphenyl)-N,N′-diphenylbenzidine (TPD), or N,N′-bis(N″,N″-diphenylaminonaphthalen-5-yl)-N,N′-diphenyl-1,5-diaminonaphthalene.

12. The organic light-emitting device of claim 1 wherein the dopant is a perylene compound, an aza-dipyridinomethene borate (ADPMB) compound, a DHMB borate compound, a bisaminostyrylarene (BASA) compound, a coumarin compound, a quinacridone compound, a dipyridinomethene borate (DPMB) compound, an indenoperylene compound, a naphthacene compound, a DCM compound, a periflanthene compound, an organometallic complex, a rare-earth metal complex, an iridium metal complex, or a platinum metal complex.

13. The organic light-emitting device of claim 1 wherein the electron-transport layer includes at least one alkali metal or alkaline earth metal, wherein the molar ratio of alkali metal or alkaline earth metal to electron-transport material in the electron-transport layer is in a range from 0.1:1 to 4:1.

14. The organic light-emitting device of claim 13 wherein the electron-transport layer includes an oxinoid compound, a phenanthroline compound, or a pyridine compound.

15. The organic light-emitting device of claim 1 wherein the electron-transport layer includes a triazine compound.

16. The organic light-emitting device of claim 13 wherein the electron-transport layer includes either an arene compound having at least four fused benzene rings or a mixture of this arene compound and an oxinoid compound, a phenanthroline compound, or a pyridine compound.

17. The organic light-emitting device of claim 13 wherein Li is included in the electron-transport layer in a concentration range of 0.5 to 10 volume % of the electron-transport layer or Cs is included in the electron-transport layer in a concentration range of 0.5 to 30 volume % of the electron transport layer.

18. The organic light-emitting device of claim 1 wherein the electron-transport layer includes at least two sublayers, wherein the sublayer adjacent to the cathode includes Li or Cs and the sublayer adjacent to the light-emitting layer:
i) does not include Li or Cs, and
ii) includes a material having a LUMO level equal to or lower than that of the host of the light-emitting layer and having a HOMO level lower than that of the host of the light-emitting layer.

19. The organic light-emitting device of claim 18 wherein the sublayer adjacent to the light-emitting layer includes an oxinoid compound, a phenanthroline compound, a pyridine compound, a triazine compound, or an arene compound having at least four fused benzene rings.

20. The organic light-emitting device of claim 18 wherein the sublayer adjacent to the cathode includes an oxinoid compound, a phenanthroline compound, a pyridine compound, a triazine compound, or an arene compound having at least four fused benzene rings.
